(19) United States
(12) Patent Application Publication
(10) Pub. No.: US 2025/0015160 A1
(43) Pub. Date: Jan. 9, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventor: Jhon-Jhy LIAW, Zhudong Township (TW)

(21) Appl. No.: 18/347,329

(22) Filed: Jul. 5, 2023

(51) Int. Cl. H01L 29/66; H01L 29/06; H01L 29/423; H01L 29/775; H01L 29/786

(52) U.S. Cl. CPC H01L 29/66439; H01L 29/0673; H01L 29/42392; H01L 29/66545; H01L 29/775; H01L 29/78696

(57) ABSTRACT

A semiconductor structure is provided. The semiconductor structure includes forming an active region over a substrate, etching the active region to form a recess, forming a sacrificial layer in the recess, forming a source/drain feature over the sacrificial layer in the recess, removing the substrate, etching the active region and the sacrificial layer to form an opening exposing a backside surface of the source/drain feature, and forming a first contact plug in the opening.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIGS. 2A and 2B are the frontside layout and the backside layout of a semiconductor structure, in accordance with some embodiments.

FIGS. 3A-1, 3A-2, 3A-3 and 3A-4 are cross-sectional views of the semiconductor structure at an intermediate stage corresponding to line Y1-Y1, line Y3-Y3, line X1-X1, and line X3-X3 of FIGS. 2A and 2B, in accordance with some embodiments of the disclosure.

FIGS. 3B-1, 3B-2, 3B-3 and 3B-4 are cross-sectional views of the semiconductor structure at an intermediate stage corresponding to line Y1-Y1, line Y3-Y3, line X1-X1, and line X3-X3 of FIGS. 2A and 2B, in accordance with some embodiments of the disclosure.

FIGS. 3C-1, 3C-2, 3C-3, 3C-4 and 3C-5 are cross-sectional views of the semiconductor structure at an intermediate stage corresponding to line Y1-Y1, line Y3-Y3, line Y4-Y4, line X1-X1 and line X3-X3 of FIGS. 2A and 2B, in accordance with some embodiments of the disclosure.

FIGS. 3D-1, 3D-2, 3D-3, 3D-4, 3D-5 and 3D-6 are cross-sectional views of the semiconductor structure at an intermediate stage corresponding to line Y1-Y1, line Y3-Y3, line Y4-Y4, line X1-X1, line X3-X3 and line Y4-Y4 of FIGS. 2A and 2B, in accordance with some embodiments of the disclosure.

FIGS. 3E-1, 3E-2, 3E-3, 3E-4, 3E-5, 3E-6, 3E-7 and 3E-8 are cross-sectional views of the semiconductor structure at an intermediate stage corresponding to line Y1-Y1, line Y2-Y2, line Y3-Y3, line Y4-Y4, line X1-X1, line X2-X2, line X3-X3 and line Y4-Y4 of FIGS. 2A and 2B, in accordance with some embodiments of the disclosure.

FIGS. 3F-1, 3F-2, 3F-3 and 3F-4 are cross-sectional views of the semiconductor structure at an intermediate stage corresponding to line Y1-Y1, line Y2-Y2, line X1-X1 and line X2-X2 of FIGS. 2A and 2B, in accordance with some embodiments of the disclosure.

FIGS. 3G-1, 3G-2, 3G-3, 3G-4, 3G-5, 3G-6, 3G-7 and 3G-8 are cross-sectional views of the semiconductor structure at an intermediate stage corresponding to line Y1-Y1, line Y2-Y2, line Y3-Y3, line Y4-Y4, line X1-X1, line X2-X2, line X3-X3 and line Y4-Y4 of FIGS. 2A and 2B, in accordance with some embodiments of the disclosure.

FIGS. 4-1 and 4-2 are a modification of the semiconductor structure of FIGS. 3G-5 and 3G-6, in accordance with some embodiments of the disclosure.

FIGS. 5-1 through 5-8 are a modification of the semiconductor structure of FIGS. 3G-1 through 3G-8, in accordance with some embodiments of the disclosure.

FIGS. 6-1 and 6-2 are a modification of the semiconductor structure of FIGS. 5-5 and 5-6, in accordance with some embodiments of the disclosure.

FIGS. 7-1 and 7-2 are a modification of the semiconductor structure of FIGS. 3G-5 and 3G-6, in accordance with some embodiments of the disclosure.

FIGS. 8-1, 8-2, 8-3 and 8-4 are a modification of the semiconductor structure of FIGS. 5-1, 5-2, 5-5 and 5-6, in accordance with some embodiments of the disclosure.

FIGS. 9A and 9B are the frontside layout and the backside layout of a semiconductor structure, in accordance with some embodiments.

FIGS. 10-1 and 10-2 are cross-sectional views of the semiconductor structure corresponding to line Y1-Y1 and line Y2-Y2 of FIGS. 9A and 9B, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure are provided. The aspect of the present disclosure is directed to a semiconductor structure with a backside power rail architecture. The semiconductor structure may include a backside metal line (e.g., a power rail) below and electrically connected to the Vdd/Vss nodes of integrated circuits (e.g., source/drain features and backside contact plugs). Therefore, the overall resistance of the BEOL (backend of lines) metal layers, and/or the complexity of the metal routing on the frontside of the substrate may be reduced, which may facilitate the continued scaling of semiconductor devices.

In accordance with some embodiments of the present disclosure, forming the semiconductor structure includes forming a sacrificial layer in a source/drain recess, and forming the source/drain feature on the sacrificial layer. As a result, the backside contact plug can be formed to have a narrower upper portion that replaces the sacrificial layer and is thus self-aligned to the source/drain feature. The parasitic capacitance between the backside contact plug and the final gate stack may be reduced. Furthermore, the backside contact plug can be formed to have a wider lower portion connected to the backside metal line, thereby improving the RC delay of the metal conductors (e.g., metal lines) and the IR voltage drop of the power supply.

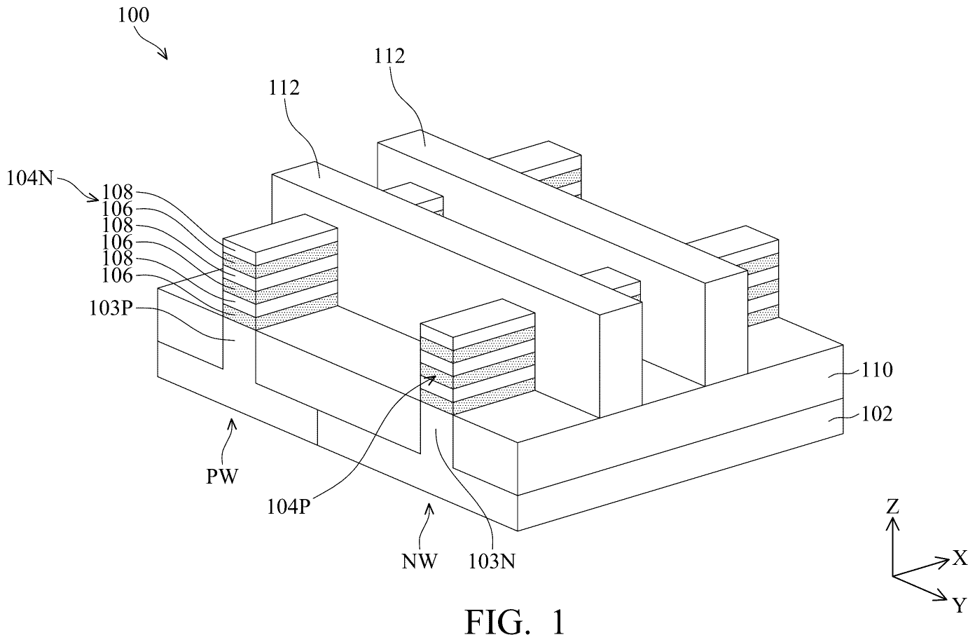

FIG. 1 is a perspective view of a semiconductor structure 100, in accordance with some embodiments of the disclosure. The semiconductor structure 100 includes a substrate 102 and fin structures 104 (including 104N and 104P) over the substrate 102, as shown in FIG. 1, in accordance with some embodiments. The substrate 102 includes a p-type well PW and an n-type well NW immediately adjacent to the p-type well PW, in accordance with some embodiments. The fin structure 104N is formed in the p-type well PW of the substrate 102, and the fin structure 104P is formed in the n-type well NW of the substrate 102, in accordance with some embodiments. The fin structures 104N and 104P are the active regions of the semiconductor structure 100, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104N includes a lower fin element 103P formed from the p-type well PW, and the fin structure 104P includes a lower fin element 103N formed from the n-type well NW, in accordance with some embodiments. The lower fin elements 103P and 103N are surrounded by an isolation structure 110, in accordance with some embodiments. Each of the fin structures 104N and 104P further includes an upper fin element formed from an epitaxial stack including alternating first semiconductor layers 106 and second semiconductor layer 108, in accordance with some embodiments. The second semiconductor layers 108 will form nanostructures (e.g., nanowires or nanosheets) and serve as the channel for the resulting semiconductor devices, in accordance with some embodiments.

The fin structures 104N and 104P extend in the X direction, in accordance with some embodiments. That is, the fin structures 104N and 104P have longitudinal axes parallel to the X direction, in accordance with some embodiments. The X direction may also be referred to as the channel-extending direction. The current of the resulting semiconductor device (i.e., nanostructure transistor) flows in the X direction through the channel. Each of the fin structures 104 is defined as several channel regions and several source/drain regions, where the channel regions and the source/drain regions are alternately arranged, in accordance with some embodiments. In this disclosure, a source/drain refers to a source and/or a drain. It is noted that in the present disclosure, a source and a drain are interchangeably used and the structures thereof are substantially the same. Gate structures 112 are formed with longitudinal axes parallel to the Y direction and extending across and/or surrounding the channel regions of the fin structures 104N and 104P, in accordance with some embodiments. The source/drain regions of the fin structures 104N and 104P are exposed from the gate structures 112, in accordance with some embodiments. The Y direction may also be referred to as a gate-extending direction.

Although two fin structures 104 are illustrated in FIG. 1, the semiconductor structure 100 may include more than two fin structures 104. In addition, FIG. 1 shows two gate structures 112 (or channel regions) for illustrative purposes and is not intended to be limiting. The number of fin structures and the gate structures may be dependent on design demand of an integrated circuit and/or performance consideration of semiconductor devices.

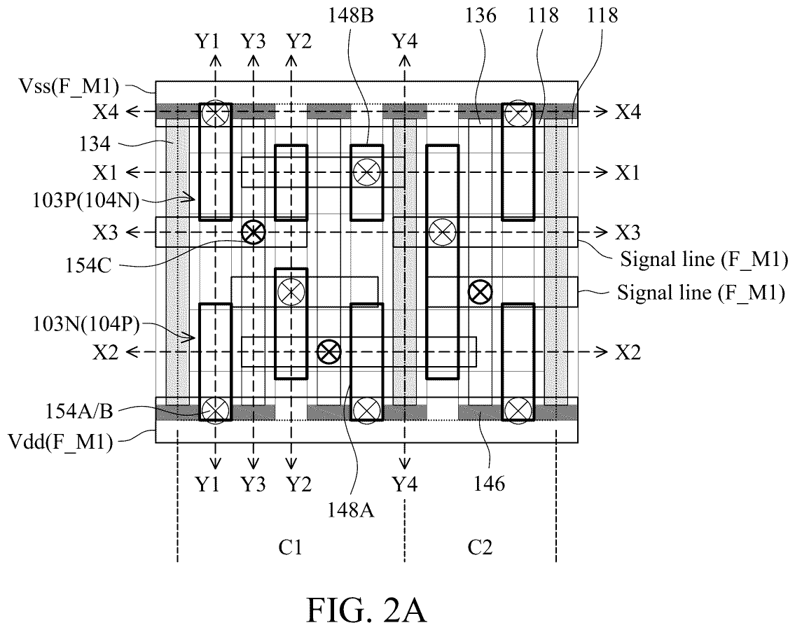

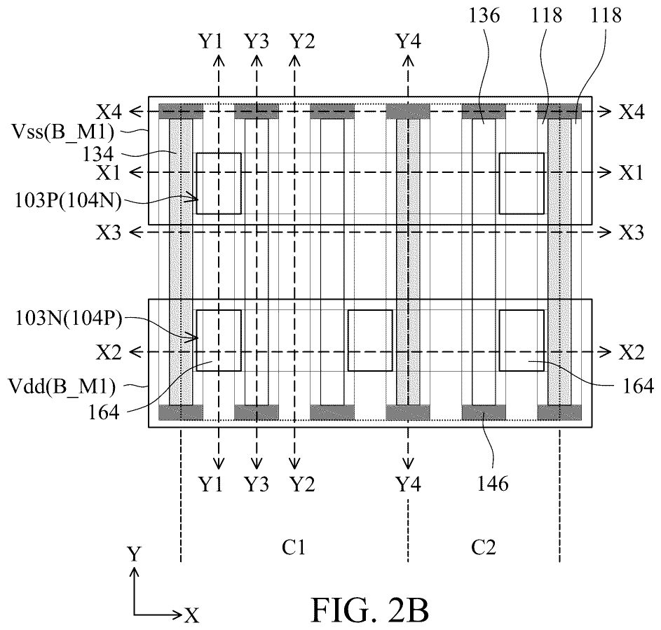

FIGS. 2A and 2B respectively illustrate the frontside layout and the backside layout of a semiconductor structure 100 with a backside power rail architecture, in accordance with some embodiments. FIGS. 2A and 2B illustrates a semiconductor structure 100 which may be or include nanostructure devices (e.g., GAA FETs), in accordance with some embodiments.

The semiconductor structure 100 includes active regions 104 (including 104N and 104P) over a substrate (as shown in FIG. 1), and final gate stacks 136 across the active regions 104, in accordance with some embodiments. The active regions 104N and 104P extend in the X direction, in accordance with some embodiments. The active regions 104N and 104P may be similar to the fin structures as shown in FIG. 1, in accordance with some embodiments.

The substrate includes a p-type well and an n-type well (not shown), in accordance with some embodiments. The p-type well and the n-type well are immediately arranged in the Y direction, in accordance with some embodiments. The active region 104N is located on the p-type well, and the active region 104P is located on the n-type well, in accordance with some embodiments. Each of the active regions 104 includes a lower fin element 103N (or 103P) and nanostructures (not shown in FIGS. 2A and 2B) formed over the lower element 103N (or 103P), in accordance with some embodiments.

The final gate stacks 136 extend in the Y direction and across the lower fin elements 103N and 103P, and wrap around the nanostructures of the active regions 104N and 104P, in accordance with some embodiments. Gate spacer layers 118 are formed along the opposite sides of the final gate stacks 136, in accordance with some embodiments. The final gate stacks 136 are combined with the nanostructures of the active regions 104 to form nanostructure transistors, in accordance with some embodiments. The nanostructure transistors are formed at the cross points between the active regions 104 and the final gate stacks 136, in accordance with some embodiments. The nanostructure transistors which are formed on the active region 104N in the p-type well are n-channel nanostructure transistors (e.g., NMOSFET), and the nanostructure transistors which are formed on the active region 104P in the n-type well are p-channel nanostructure transistors (e.g., PMOSFET), in accordance with some embodiments.

The semiconductor structure 100 is used to form integrated circuits, each of which includes several functional circuits interconnected with each other, in accordance with some embodiments. FIGS. 2A and 2B illustrates an area of the semiconductor structure 100 (or the substrate) which is defined as cell regions C1 and C2, in accordance with some embodiments.

Functional circuits are disposed in the cell regions C1 and C2, in accordance with some embodiments. The boundaries (or edges) of the cell regions C1 and C2 are dictated as dashed lines. The cell regions C1 and C2 are arranged in a row (in the X direction), in accordance with some embodiments. In some embodiments, the cell regions C1 and C2 are standard (STD) cells and have the same cell height (in the Y direction). The cell regions C1 and C2 may have rectangular shapes in the plan view, and the edges of the cell region C extend in the X direction and the Y direction, in accordance with some embodiments.

In some embodiments, the cell region C1 is a NAND cell where a NAND circuit is formed in it. In some embodiments, the cell region C2 is an inverter cell where an inverter circuit is formed in it. Although FIGS. 2A and 2B illustrate the NAND cell and the inverter cell, the cell regions C1 and C2 may be any suitable STD cell regions, e.g., NOR, AND, OR, Flip-Flop, and/or SCAN cell regions, and/or memory cell regions such as SRAM cell region.

Fin isolation structures 134 extend in the Y direction and vertically extend into the active regions 104N and 104P, in accordance with some embodiments. Gate spacer layers 118 are also formed along the opposite sides of the fin isolation structures 134, in accordance with some embodiments. The fin isolation structures 134 are located on the boundaries of the cell regions C1 and C2 with respect to the X direction (extending in the Y direction), in accordance with some embodiments.

Gate isolation structures 146 are formed in and/or through the final gate stacks 136, the fin isolation structures 134 and the gate spacer layers 118, in accordance with some embodiments. The gate isolation structures 146 are located on and arranged along the boundaries of the cell regions C1 and C2 with respect to the Y direction (extending in the X direction), in accordance with some embodiments.

Frontside contact plugs 148 (including 148A and 148B) are formed over the source/drain regions of the active regions 104N and 104P, in accordance with some embodiments. The contact plugs 148 are electrically connected to the source or drain terminals (e.g., the source/drain regions of the active regions 104) of the nanostructure transistors, in accordance with some embodiments. The contact plugs 148A are electrically connected to frontside power supply lines and may also serve as Vdd/Vss nodes of the integrated circuits of the cell regions C1 and C2, in accordance with some embodiments. The contact plugs 148B are electrically connected to signal lines and may also serve as non-Vdd/Vss nodes of the integrated circuits of the cell regions C1 and C2.

Vias 154A/B are formed on and electrically connected to the frontside contact plug 148A and 148B and may also be referred to as source/drain vias, in accordance with some embodiments. Vias 154C are formed on the final gate stacks 136 and may also be referred to as gate vias, in accordance with some embodiments.

A frontside metal layer (e.g., frontside first-level metal layer (F_M1)) is formed on and electrically connected to the vias 154A-C, in accordance with some embodiments. The frontside metal layer F_M1 includes several conductive lines (tracks) e.g., power supply lines and signal lines, in accordance with some embodiments. The power supply lines include a Vdd frontside power rail providing positive voltage and a Vss frontside power rail which may be an electrical ground, in accordance with some embodiments. The signal lines are configured for signal transmission and are electrically isolated from the power supply lines, in accordance with some embodiments.

The lines of the frontside metal layer F_M1 extend in the X direction, in accordance with some embodiments. The power supply lines (Vdd and Vss) extend along and overlap the edges of the cell regions C1 and C2 with respect to the Y direction, in accordance with some embodiments. The Vss frontside power rail is electrically connected to the Vss node (e.g., source terminals) of the n-channel transistors through the vias 154A and the contact plugs 148A, in accordance with some embodiments. The Vdd frontside power rail is electrically connected to the Vdd node (e.g., source terminals) of the p-channel transistors through the vias 154A and the contact plugs 148A, in accordance with some embodiments.

The signal lines are located between the power supply lines, in accordance with some embodiments. The signal lines are electrically connected to the final gate stacks 136 and the non-Vdd/Vss nodes (e.g., drain terminals) of the n-channel transistors and p-channel transistors through the vias 154B and 154C and the contact plugs 148B, in accordance with some embodiments.

Backside contact plugs 164 are formed below the source/drain regions of the active regions 104N and 104P, in accordance with some embodiments. The contact plugs 164 are electrically connected to the source terminals of the nanostructure transistors, in accordance with some embodiments. The contact plugs 164 are electrically connected to backside power supply lines and may also serve as Vdd/Vss nodes of the integrated circuits of the cell regions C1 and C2, in accordance with some embodiments.

A backside metal layer (e.g., backside first-level metal layer (B_M1)) is formed below and electrically connected to the backside contact plugs 164, in accordance with some embodiments. The backside metal layer B_M1 includes several conductive lines (tracks) e.g., power supply lines, in accordance with some embodiments. The power supply lines include a Vdd backside power rail providing positive voltage and a Vss backside power rail which may be an electrical ground, in accordance with some embodiments.

The lines of the backside metal layer B_M1 extend in the X direction, in accordance with some embodiments. The power supply lines (Vdd and Vss) extend along and overlap the edges of the cell regions C1 and C2 with respect to the Y direction and the active regions 104N and 104P, in accordance with some embodiments. The Vss backside power rail is electrically connected to the Vss node (e.g., source terminals) of the n-channel transistors through the contact plugs 164, in accordance with some embodiments. The Vdd backside power rail is electrically connected to the Vdd node (e.g., source terminals) of the p-channel transistors through the contact plugs 164, in accordance with some embodiments.

As the scale of the semiconductor devices continues to shrink, the scaling of metal layers in BEOL has been touched by the limitation on both resistance and capacitance due to increasingly smaller line width and line space. As a result, the performance improvement (e.g., increase in speed) of semiconductor devices (e.g., logic circuits) cannot rely solely on the device boosting, but also needs to concern about the RC delay of the metal conductors (e.g., metal lines) as well as IR voltage drop of the power supply (e.g., Vdd and Vss truly voltage position during operation for logic circuit). The backside power rail can provide a backend metal routing for the semiconductor devices on the backside of the substrate, thereby reducing the overall resistance (e.g., contact resistance and/or sheet resistance) of the BEOL metal layers, and/or reducing the complexity of the metal routing on the frontside of the substrate. For example, the metal line density may be relaxed, and/or the metal line spacing may be increased. Therefore, the backside power rail architecture may facilitate the continued scaling of semiconductor devices.

In some embodiments, the external power is supplied from the backside metal layers of the semiconductor structure 100 to the frontside metal layers of the semiconductor structure 100 through the backside contact plug 164, the source/drain terminals of the FETs, the frontside contact plugs 148A and the vias 154A. In some embodiments, the power rails are disposed on the dual sides of the semiconductor structure 100, which may further reduce the total resistance of the metal layer.

FIGS. 2A and 2B further illustrates reference cross-sections that are used in later figures. Cross-section X1-X1 is in a plane parallel to the longitudinal axis (X direction) of the active region 104N and through the active region 104N, in accordance with some embodiments. Cross-section X2-X2 is in a plane parallel to the longitudinal axis (X direction) of the active region 104P and through the active region 104P, in accordance with some embodiments. Cross-section X3-X3 is in a plane parallel to the longitudinal axis (X direction) of the active regions 104 and through between the active regions 104N and 104P, in accordance with some embodiments. Cross-section X4-X4 is in a plane parallel to the longitudinal axis (X direction) of the active regions 104 and through the Vss power rails, in accordance with some embodiments.

Cross-section Y1-Y1 is in a plane parallel to the longitudinal axis (Y direction) of the final gate stack 136 and across two Vdd/Vss nodes, in accordance with some embodiments. Cross-section Y2-Y2 is in a plane parallel to the longitudinal axis (Y direction) of the final gate stack 136 and across two non-Vdd/Vss nodes, in accordance with some embodiments. Cross-section Y3-Y3 is in a plane parallel to the longitudinal axis (Y direction) of the final gate stack 136 and through the final gate stack 136, in accordance with some embodiments. Cross-section Y4-Y4 is in a plane parallel to the longitudinal axis (Y direction) of the final gate stack 136 and through the fin isolation structure 134, in accordance with some embodiments.

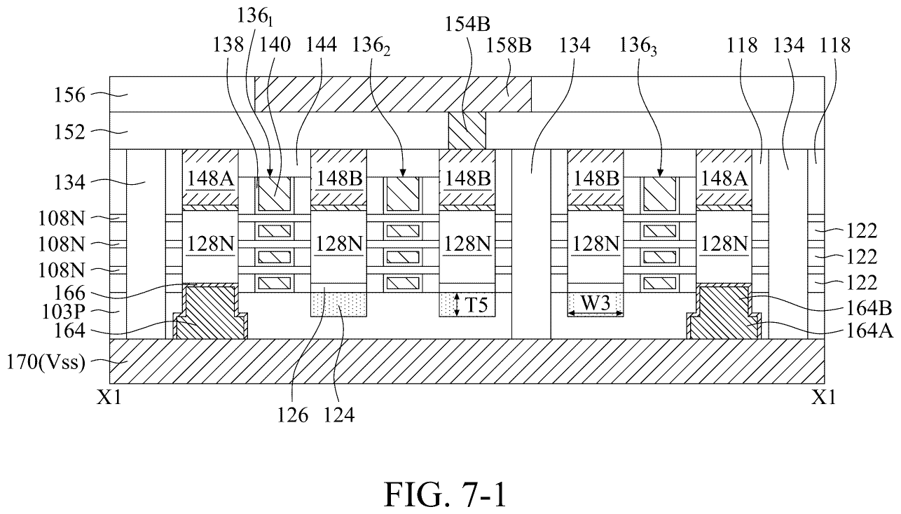

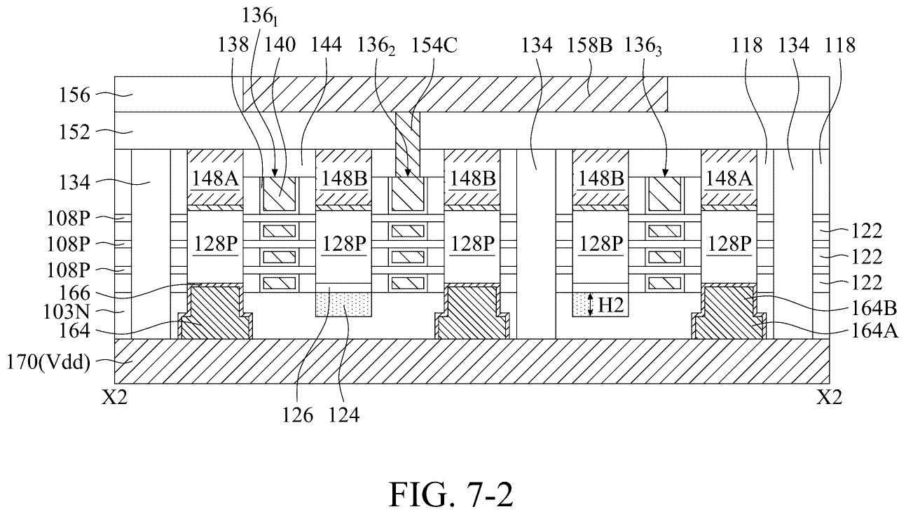

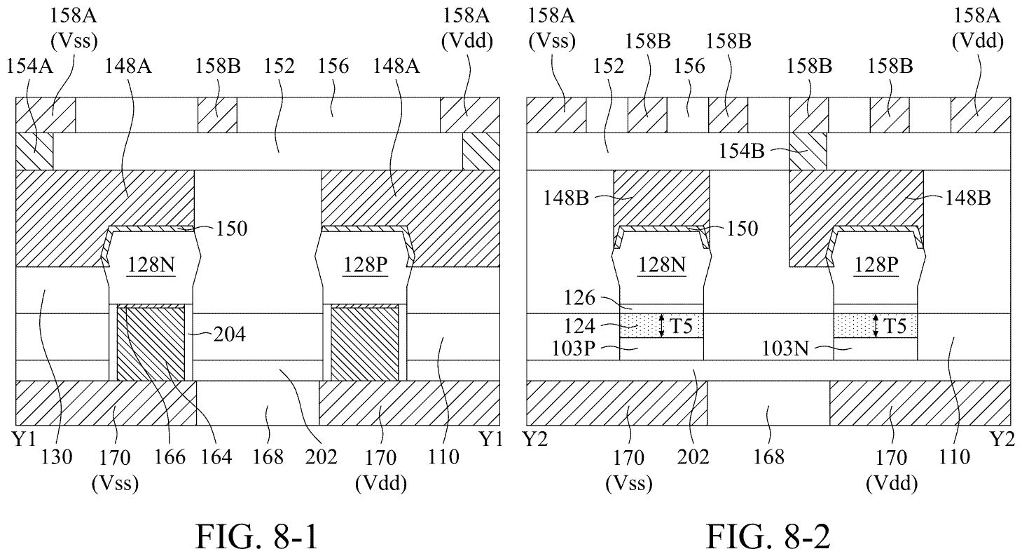

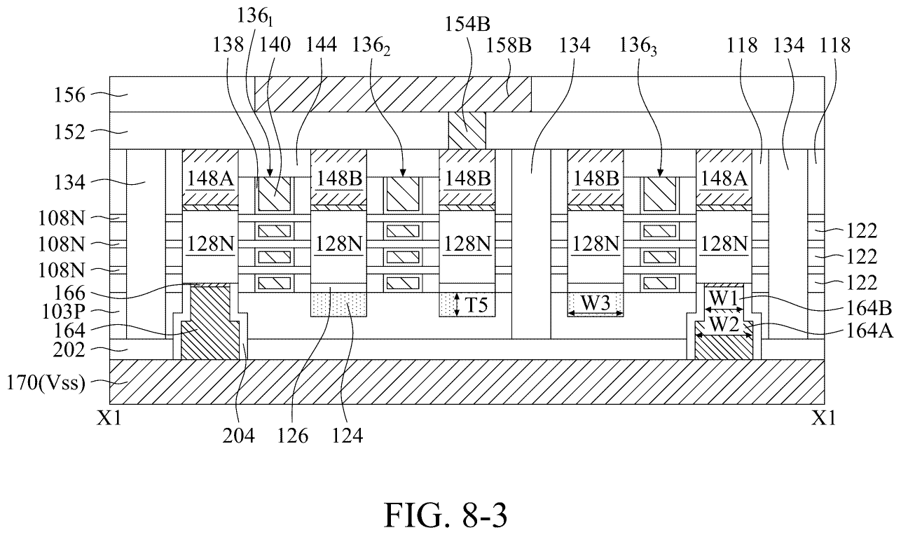

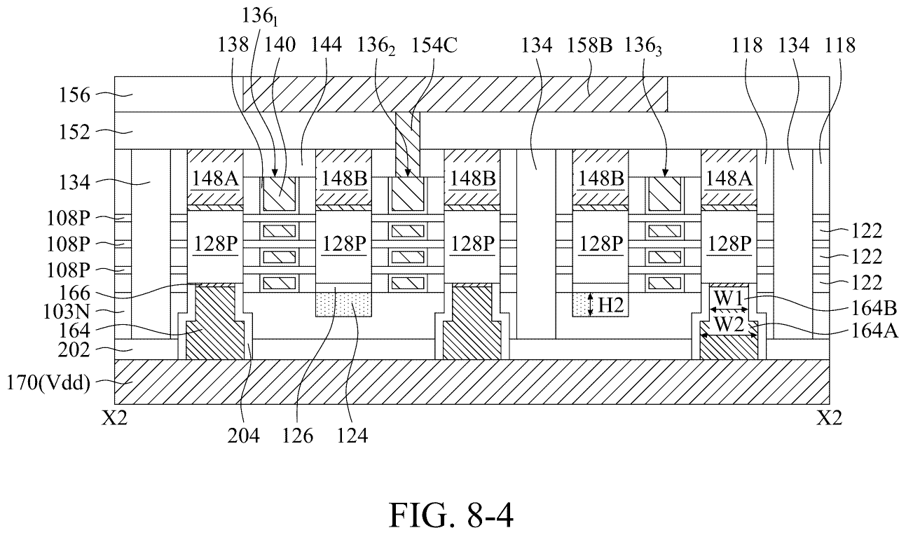

FIGS. 3A-1 through 3G-8 are cross-sectional views illustrating the formation of the semiconductor structure 100 of FIGS. 2A and 2B at various intermediate stages, in accordance with some embodiments of the disclosure.

FIGS. 3A-1 to 3A-4 illustrate cross-sectional views of the semiconductor structure 100 after the formation of active regions 104 (including 104N and 104P), an isolation structure 110, dummy gate structures 112 (including 112₁ to 112₆) and gate spacer layers 118 respectively corresponding to line Y1-Y1, line Y3-Y3, line X1-X1 and line X3-X3, in accordance with some embodiments.

A substrate 102 is provided, as shown in FIGS. 3A-1 to 3A-4, in accordance with some embodiments. The substrate 102 may be a portion of a semiconductor wafer, a semiconductor chip (or die), and the like. In some embodiments, the substrate 102 is a silicon substrate. The frontside surface of the substrate 102 (the frontside of the semiconductor structure 100) faces upward, in accordance with some embodiments.

In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

N-type dopants (such as phosphorus or arsenic) may be implanted into the substrate 102, thereby forming an n-type well (not shown), in accordance with some embodiments. P-type dopants (such as boron or BF₂) may be implanted into the substrate 102, thereby forming a p-type well (not shown), in accordance with some embodiments. In some embodiments, the respective concentrations of the dopants in the wells are in a range from about 10¹⁶/cm⁻³ to about 10¹⁸/cm⁻³. In some embodiments, the ion implantation processes may be performed several times with different dosages and different energy intensities. In some embodiments, the ion implantation process may include anti-punch through (APT) implant.

Active regions 104 (including 104N and 104P) are formed over the substrate 102, as shown in FIGS. 3A-1 to 3A-3, in accordance with some embodiments. The active region 104N is formed in the p-type well, and the active region 104P is formed in the n-type well, in accordance with some embodiments. In some embodiments, the active regions 104N and 104P extend in the X direction. That is, the active regions 104N and 104P have longitudinal axes parallel to the X direction, in accordance with some embodiments.

The formation of the active regions 104N and 104P includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor devices (such as nanostructure transistors), in accordance with some embodiments.

The formation of the active regions 104N and 104P further includes patterning the epitaxial stack and the underlying p-type and n-type wells using photolithography and etching processes, thereby forming trenches and the active regions 104 protruding from between trenches, in accordance with some embodiments. The portion of the p-type well protruding from between the trenches serves as a lower fin element 103P of the active region 104N, and the portion of the n-type well NW protruding from between the trenches serves as a lower fin element 103N of the active region 104P, in accordance with some embodiments. A remainder of the epitaxial stack (including the first semiconductor layers 106 and the second semiconductor layers 108) serves as the upper fin elements of the active regions 104N and 104P, in accordance with some embodiments. In some embodiments, the active regions 104N and 104P are the fin structures 104N and 104P as shown in FIG. 1.

In some embodiments, each of the first semiconductor layers 106 has a thickness T1 in a range from about 6 nm to about 15 nm. In some embodiments, each of the second semiconductor layers 108 has a thickness T2 in a range from about 4 nm to about 8 nm. In some embodiments, the pitch of the second semiconductor layers 108 (e.g., the sum of thicknesses T1 and T2) is in a range from about 10 nm to about 23 nm. The thickness of the second semiconductor layers 108 may be greater than, equal to, or less than the first semiconductor layers 106, depending on the amount of gate materials to be filled in spaces where the first semiconductor layers 106 are removed. Although three first semiconductor layers 106 and three second semiconductor layers 108 are shown in FIGS. 3A-1 to 3A-3, the number is not limited to three, and can be two or four, and is less than 10.

An isolation structure 110 is formed to surround the lower fin elements 103P and 103N of the active regions 104N and 104P, as shown in FIGS. 3A-1, 3A-2 and 3A-4, in accordance with some embodiments. The isolation structure 110 is configured to electrically isolate the active regions 104 from each other and is also referred to as shallow trench isolation (STI) feature, in accordance with some embodiments. The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active regions 104, in accordance with some embodiments. The planarization may be chemical mechanical polishing (CMP), etching back process, or a combination thereof. The insulating material is then recessed by an etching process (such as dry plasma etching and/or wet chemical etching) until the upper fin elements of the active regions 104 are exposed, in accordance with some embodiments. The recessed insulating material serves as the isolation structure 110, in accordance with some embodiments.

Dummy gate structures 112 (including 112₁-112₆) are formed across the active regions 104N and 104P, as shown in FIGS. 3A-2 to 3A-4. The dummy gate structures 112 are configured as sacrificial structures and will be replaced with the final gate stacks and the fin isolation structures, in accordance with some embodiments. In some embodiments, the dummy gate structures 112 extend in the Y direction. That is, the dummy gate structures 112 have longitudinal axes parallel to the Y direction, in accordance with some embodiments. The dummy gate structures 112 surround the channel regions of the active regions 104N and 104P, in accordance with some embodiments. The dummy gate structures 112 may be similar to the gate structures 112 shown in FIG. 1.

Each of the dummy gate structures 112 includes a dummy gate dielectric layer 114 and a dummy gate electrode layer 116 over the dummy gate dielectric layer, in accordance with some embodiments. In some embodiments, the dummy gate dielectric layer 114 is conformally formed along the upper fin elements of the active regions 104. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO. In some embodiments, the dielectric material is deposited using ALD, CVD, thermal oxidation, physical vapor deposition (PVD), another suitable technique, or a combination thereof. In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof.

In some embodiments, the formation of the dummy gate structure 112 includes globally and conformally depositing a dielectric material for the dummy gate dielectric layer 114 over the semiconductor structure 100, depositing a material for the dummy gate electrode layer 116 over the dielectric material, planarizing the material for the dummy gate electrode layer 116, and patterning the material for the dummy gate electrode layer 116 and the dielectric material into the dummy gate structures 112. The patterning process includes forming a patterned hard mask layer (not shown) over the material for the dummy gate electrode layer 116, in accordance with some embodiments. The hard mask layer corresponds to and overlaps the channel region of the active regions 104, in accordance with some embodiments. The materials for dummy gate dielectric layer 114 and the dummy gate electrode layer 116, uncovered by the patterned hard mask layer, are etched away until the source/drain regions of the active regions 104 are exposed, in accordance with some embodiments. In some embodiments, the dummy gate electrode layer 116 has a dimension L1 in the X direction. In some embodiments, the dimension L1 is in a range from 6 nm to about 20 nm.

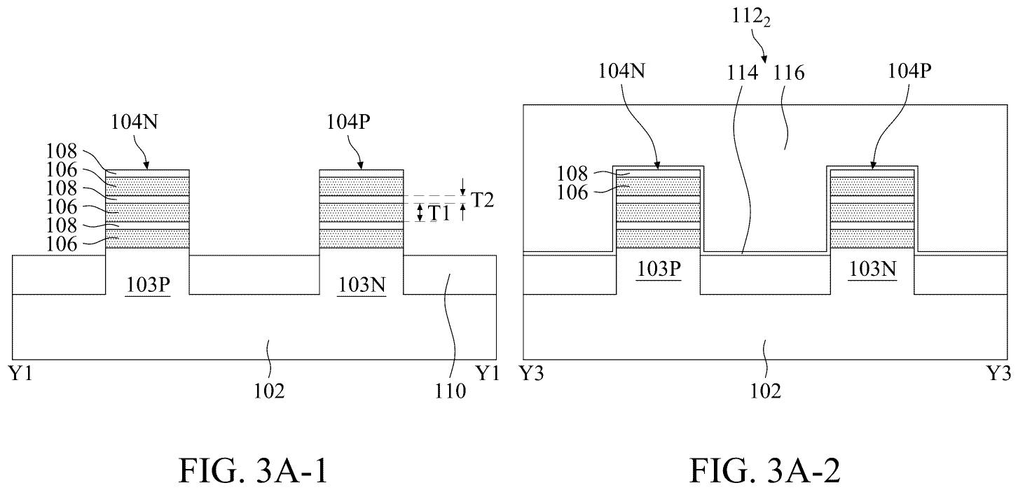

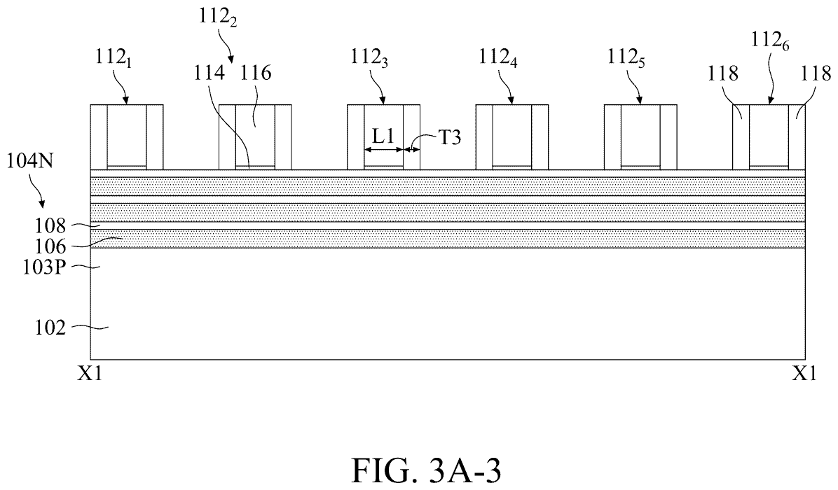

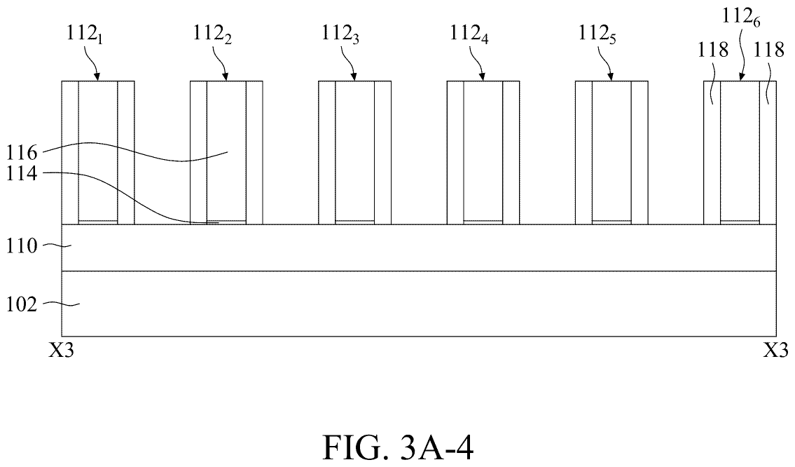

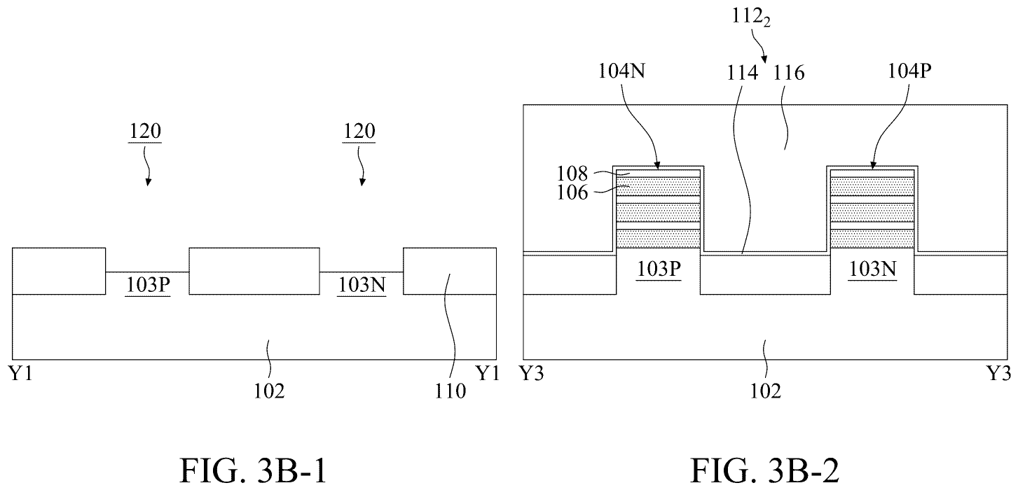

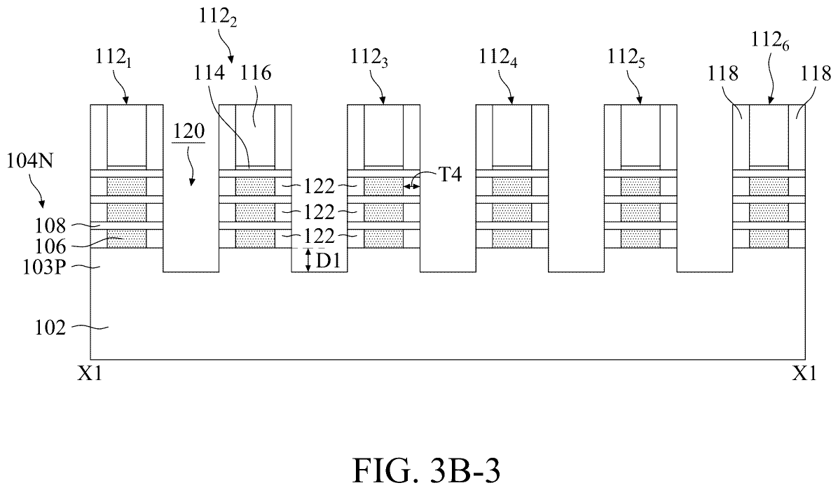

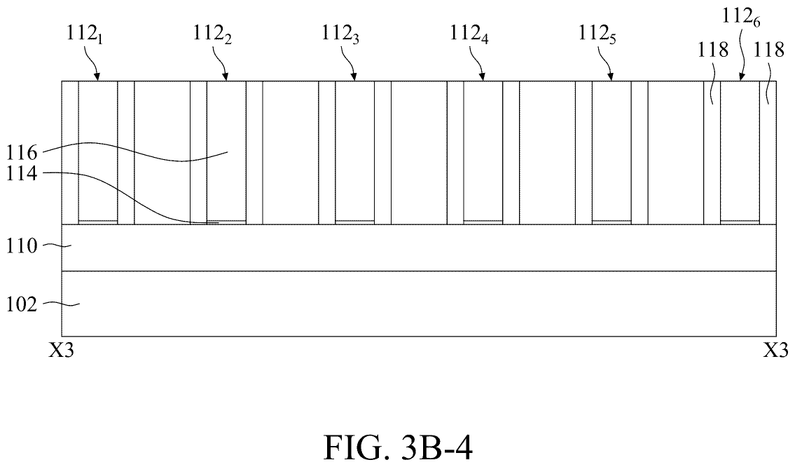

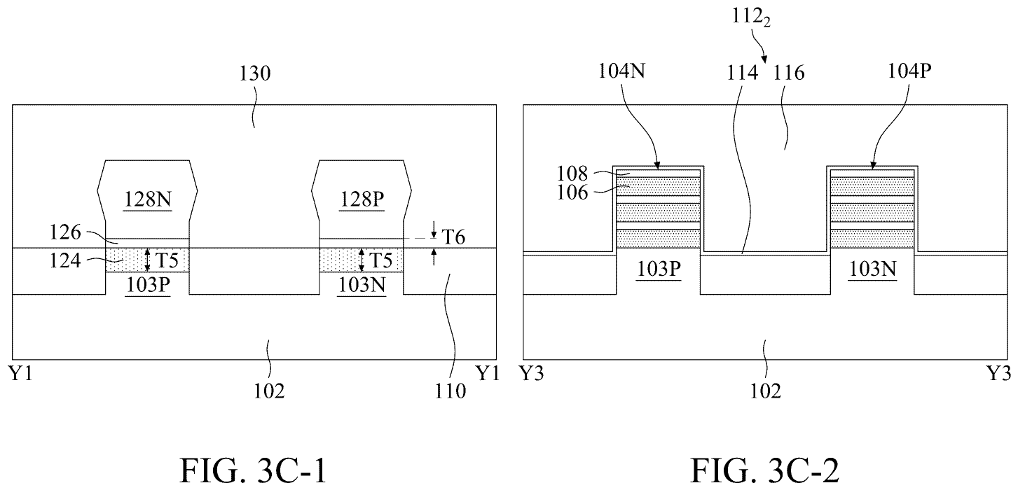

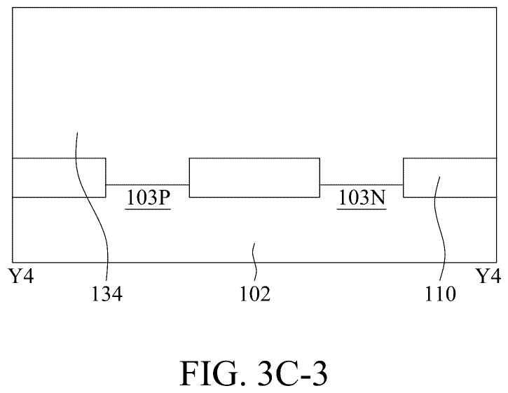

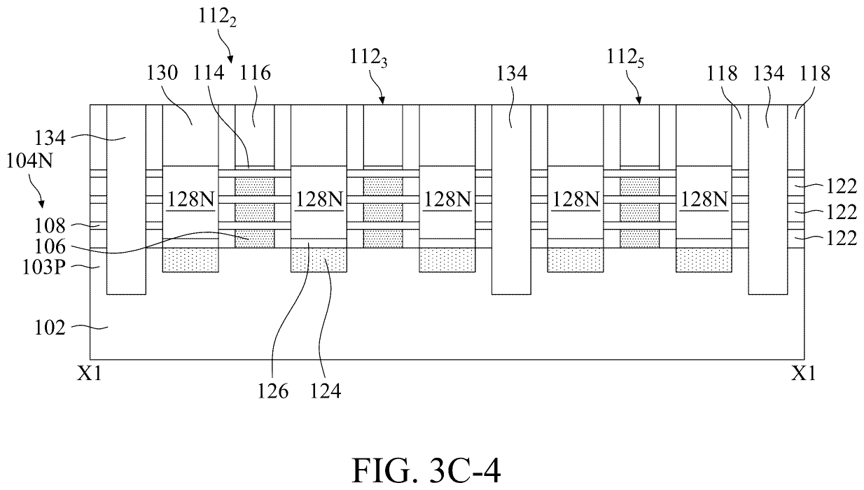

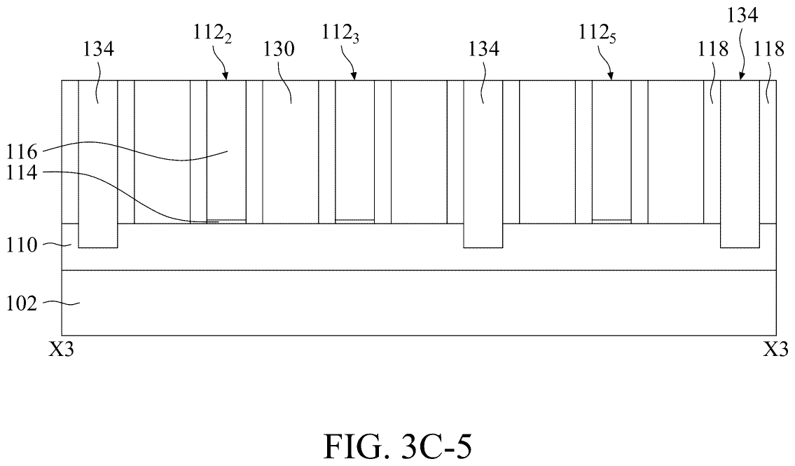

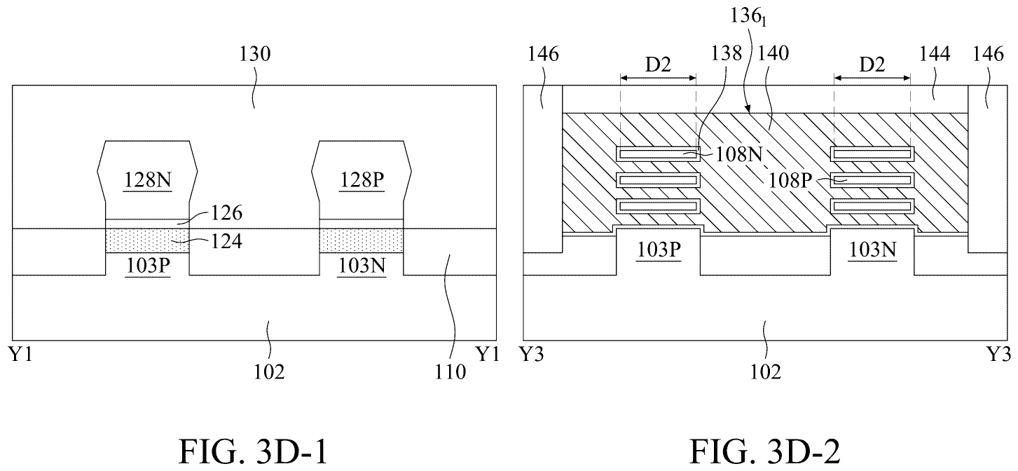

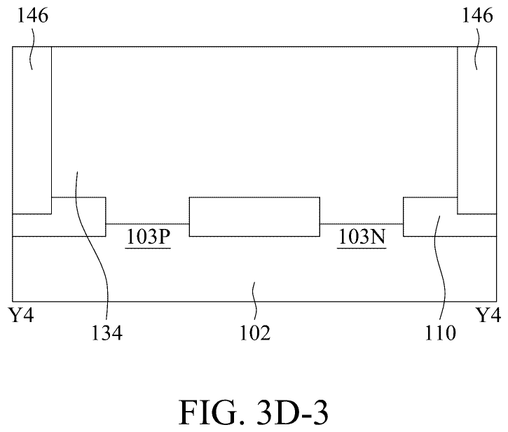

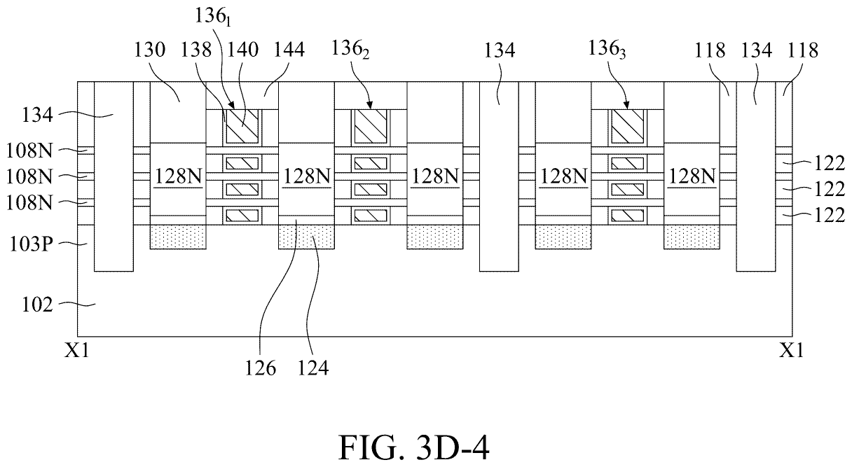

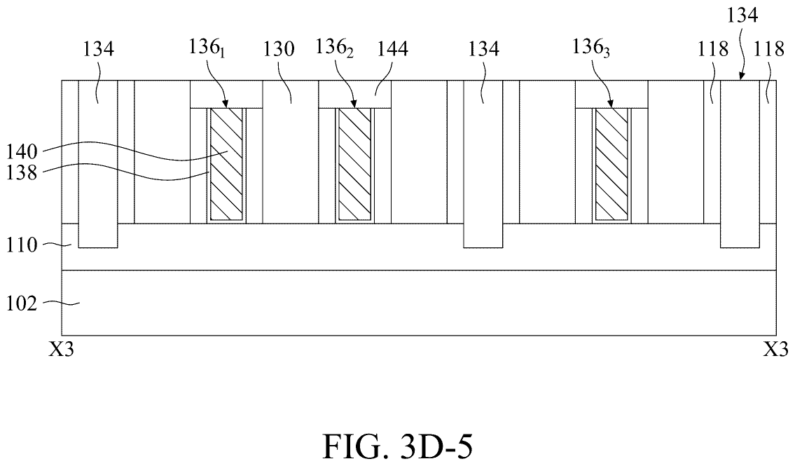

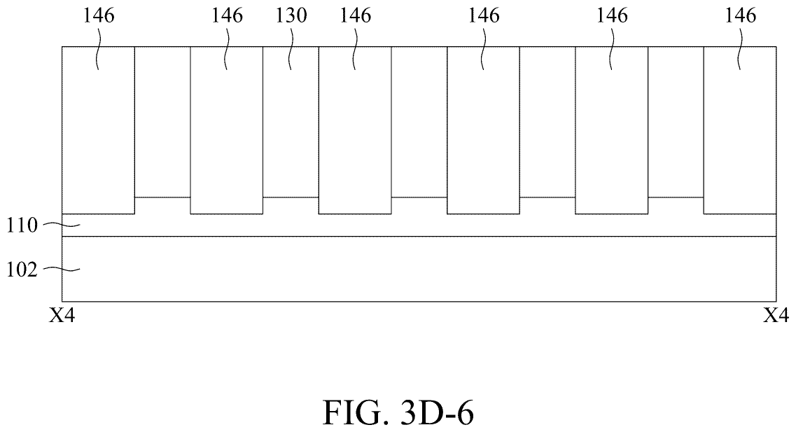

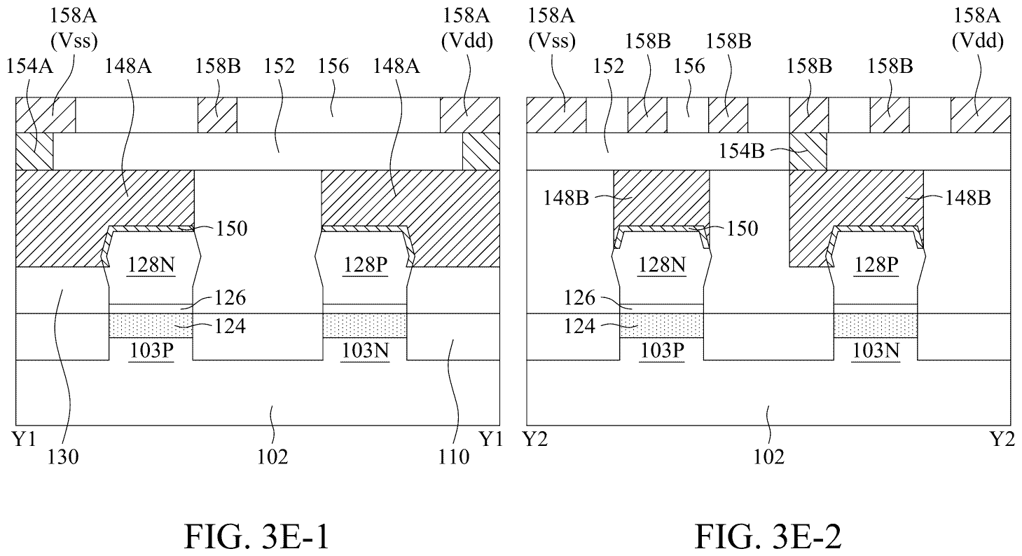

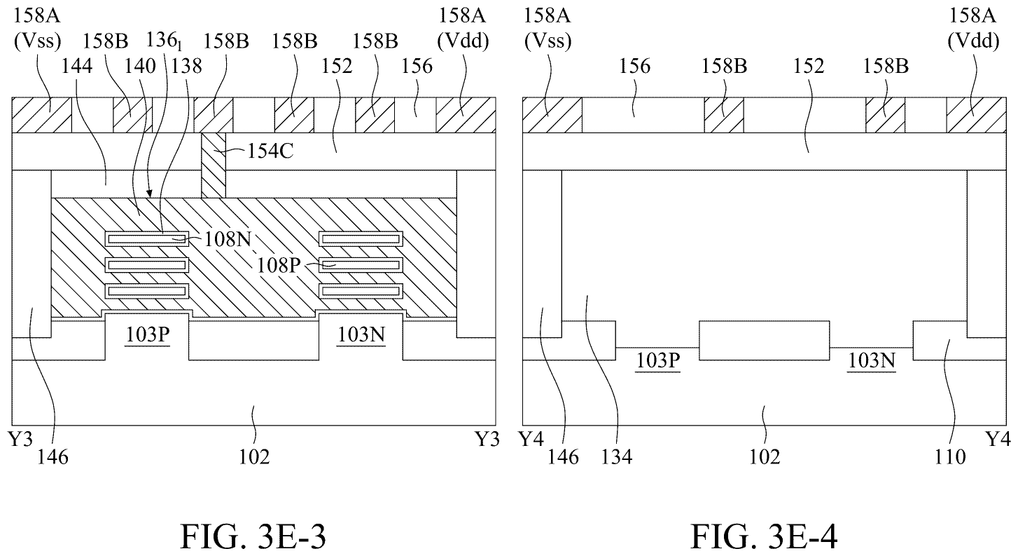

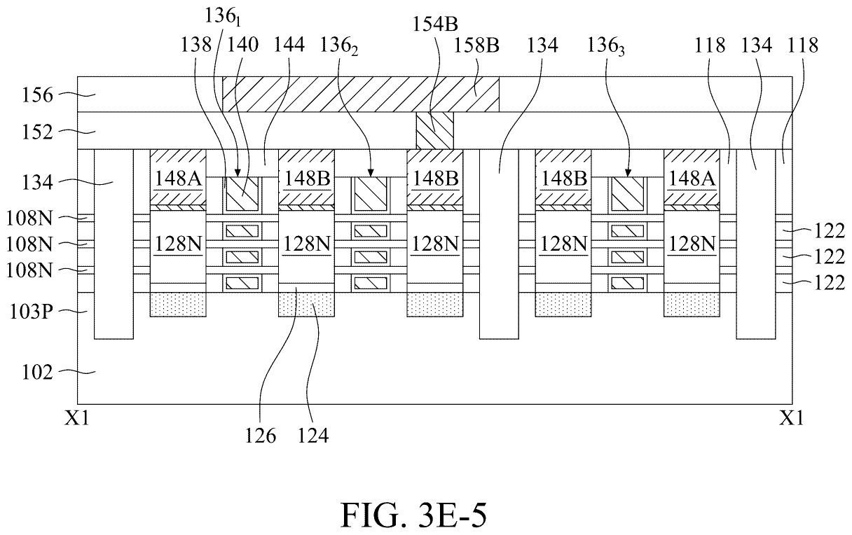

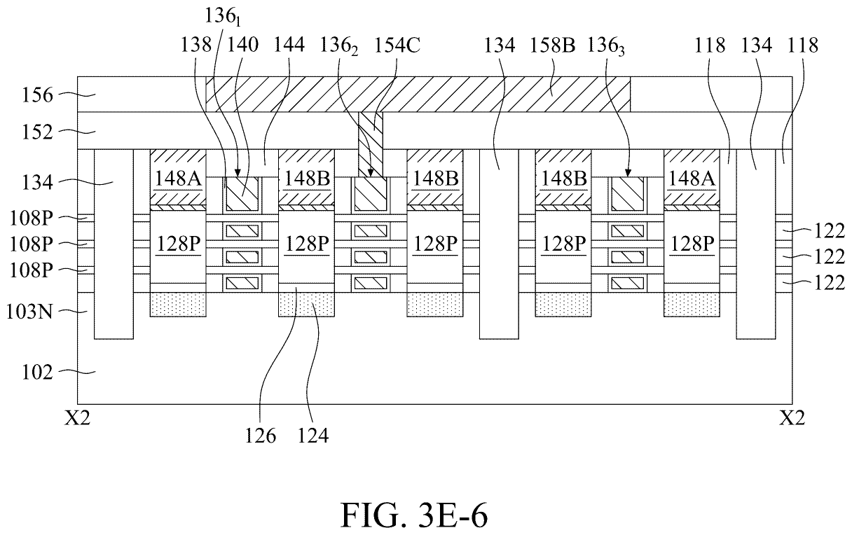

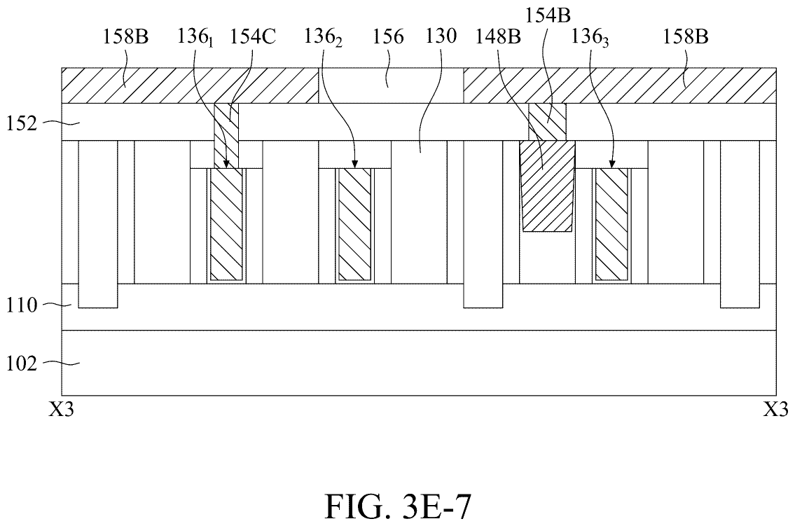

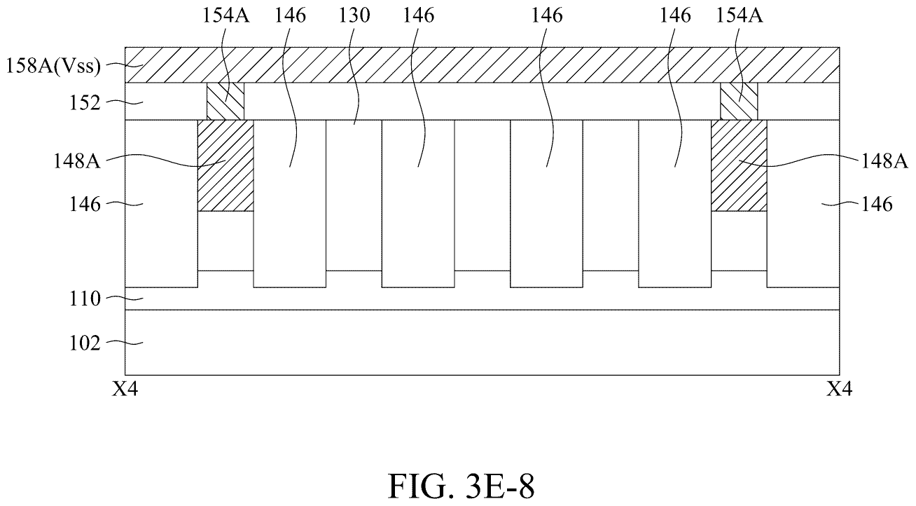

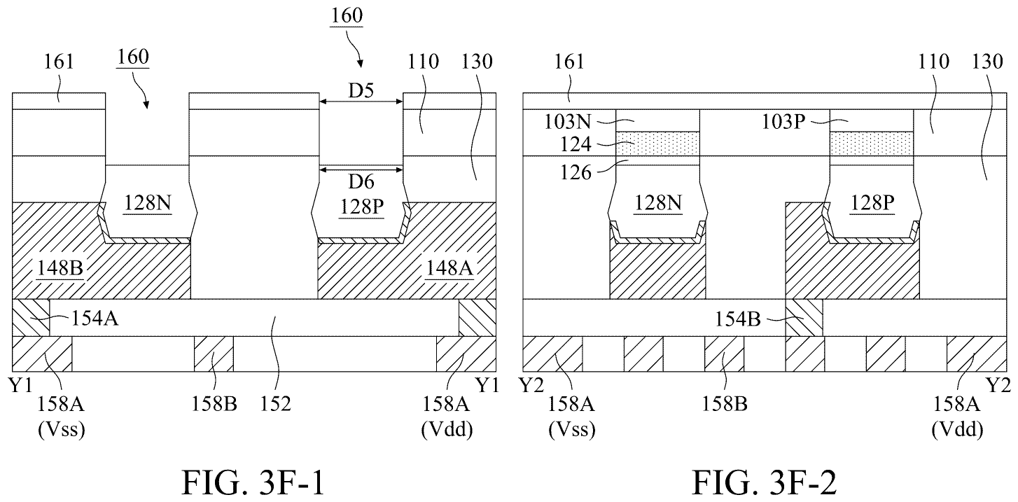

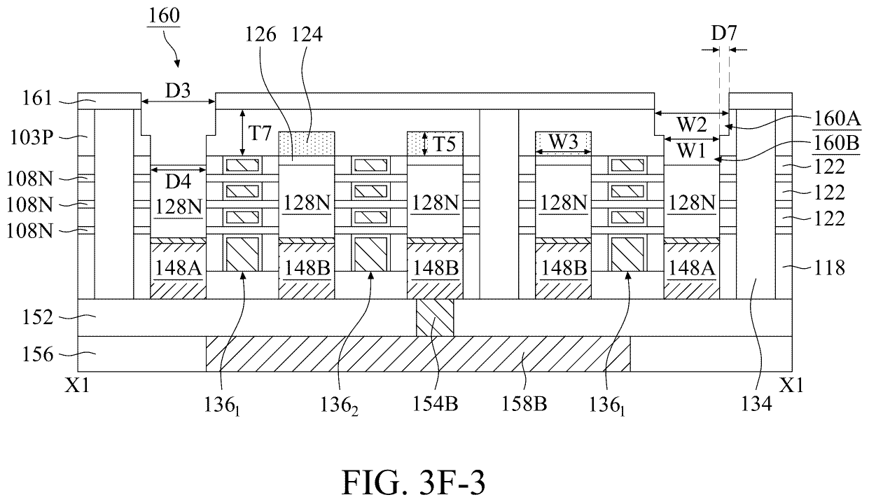

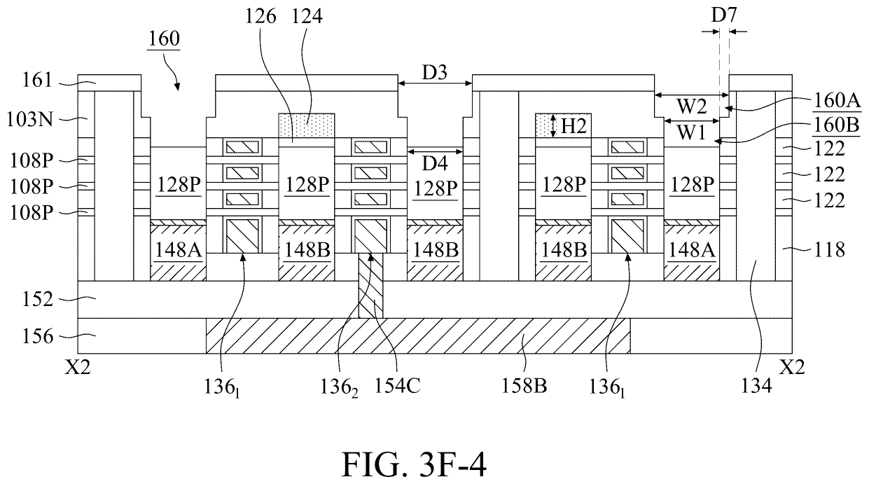

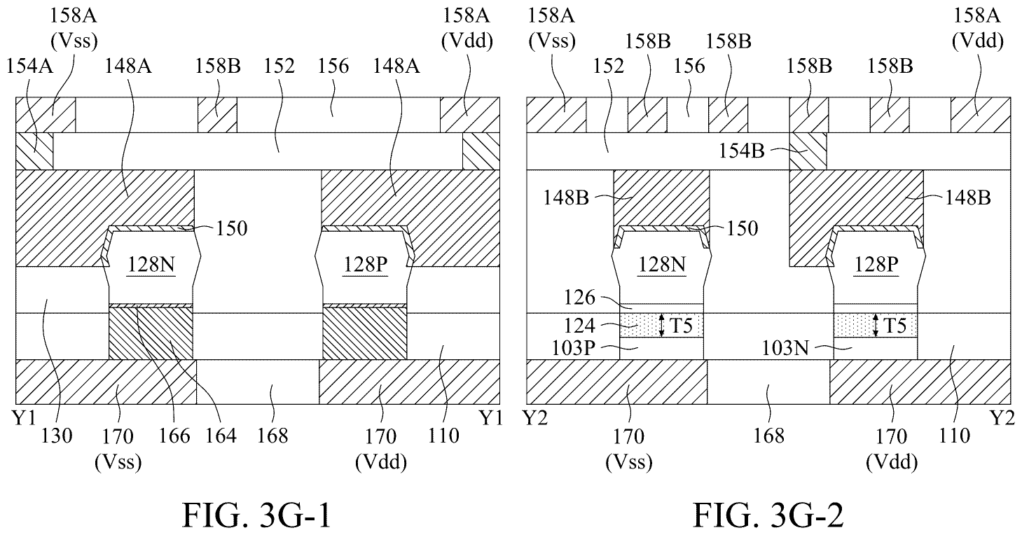

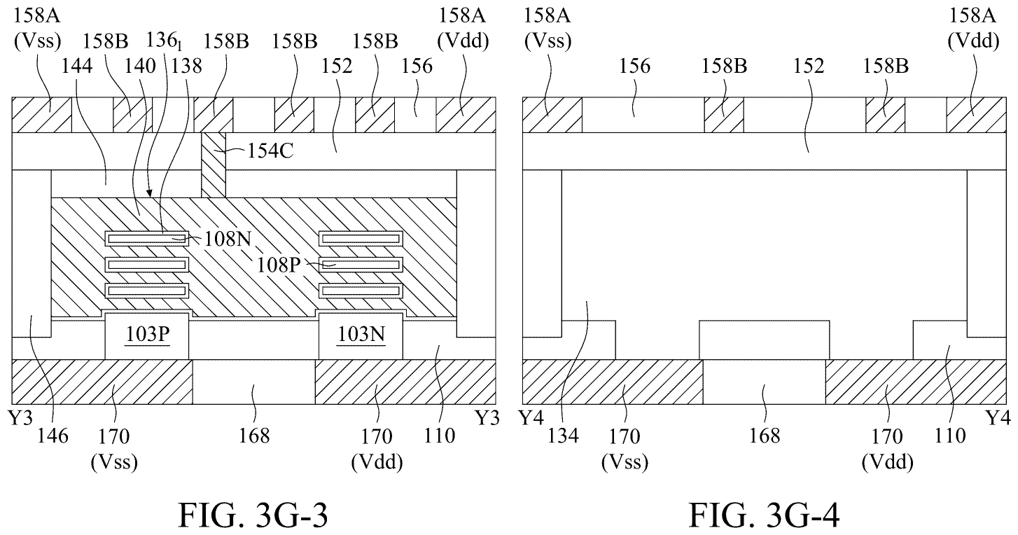

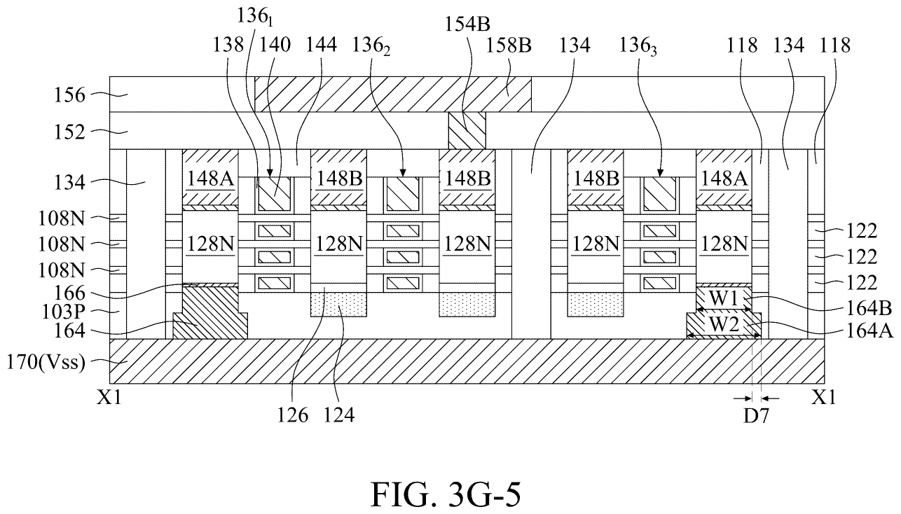

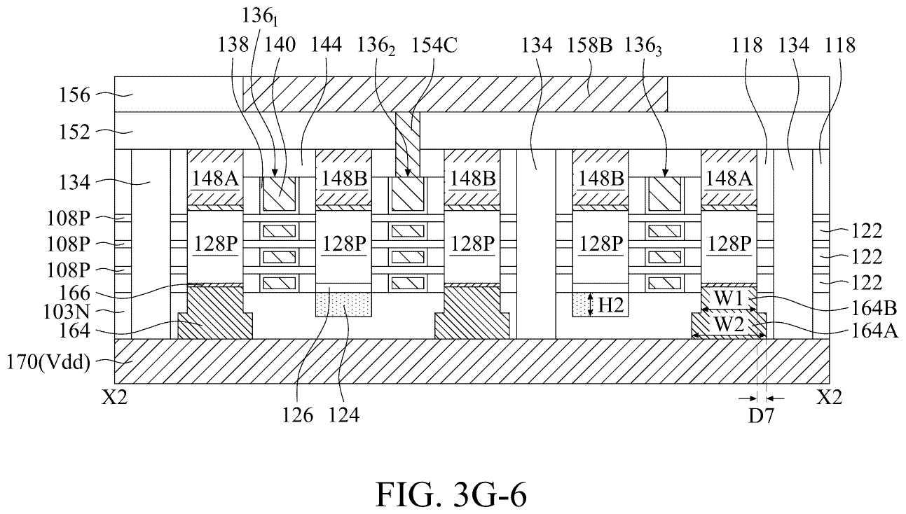

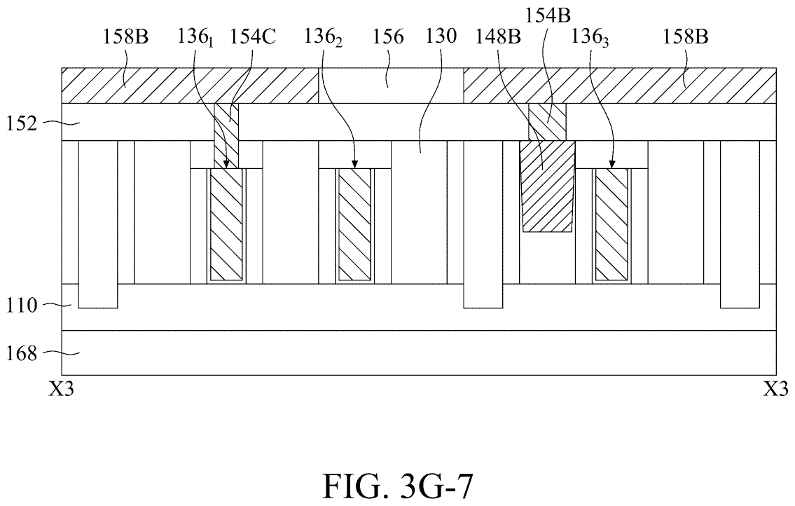

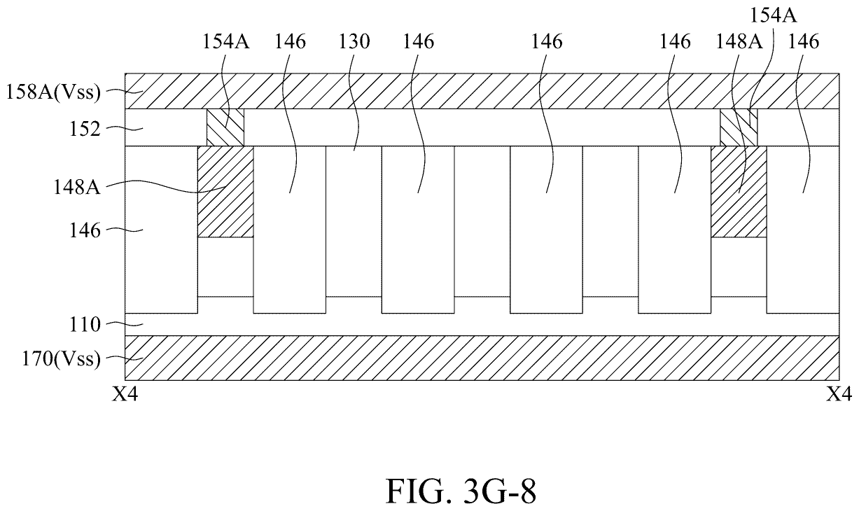

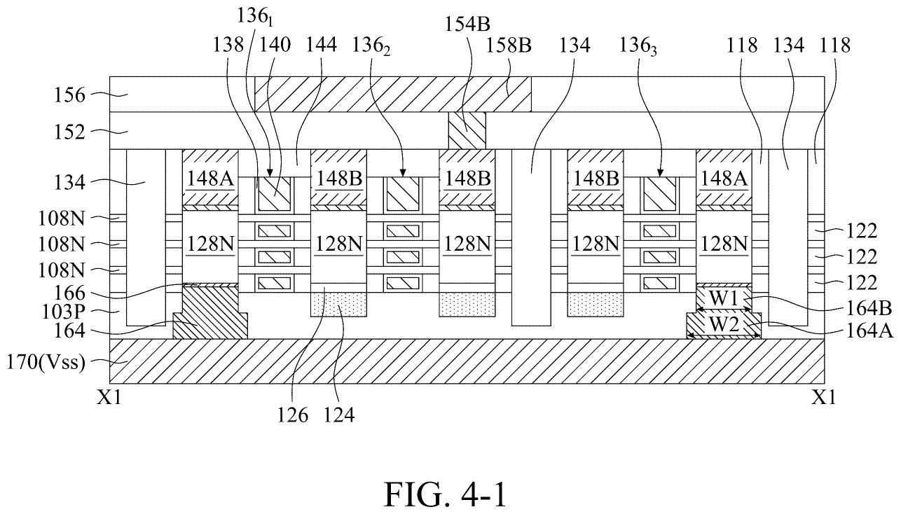

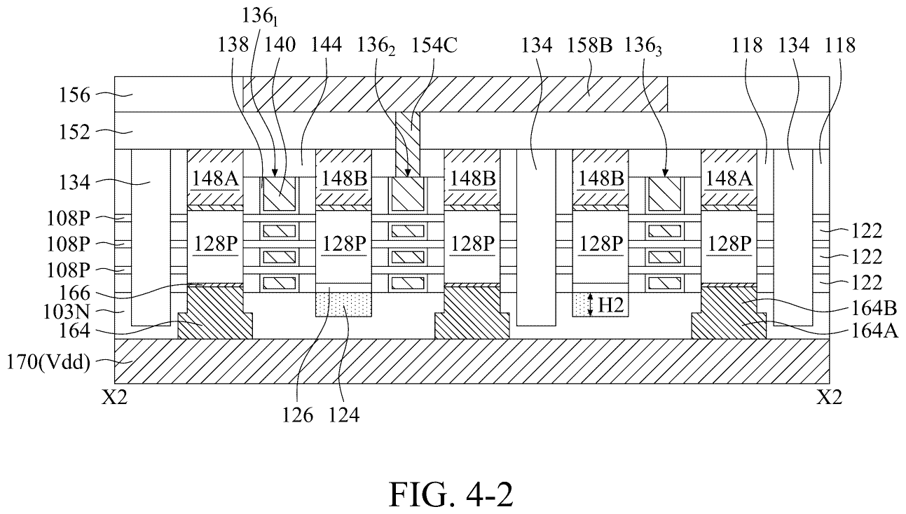

Gate spacer layers 118 are formed over the semiconductor structure 100, as shown in FIGS. 3A-3 and 3A-4, in accordance with some embodiments. The gate spacer layers 118 extend along, and cover, the opposite sides of the dummy gate structures 112, in accordance with some embodiments. In some embodiments, the gate spacer layers 118 extend in the Y direction. That is, the gate spacer layers 118 have a longitudinal axis parallel to the Y direction, in accordance with some embodiments. The gate spacer layers 118 are used to offset the subsequently formed source/drain features and separate the source/drain features from the gate structure, in accordance with some embodiments. The gate spacer layers 118 may be also referred to as top spacer layers.

In some embodiments, the gate spacer layers 118 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), a multilayer thereof, or a combination thereof. In some embodiments, the gate spacer layers 118 are made of low-k dielectric materials. For example, the dielectric constant (k) values of the gate spacer layers 118 may be lower than a k-value of silicon oxide (SiO), such as lower than 4.2, equal to or lower than about 3.9, such as in a range from about 3.5 to about 3.9. In some embodiments, the gate spacer layers 118 may include a porous version of an existing dielectric material or an air gap within the dielectric material to have a lower dielectric constant.

In some embodiments, the formation of the gate spacer layers 118 includes conformally depositing dielectric materials for the gate spacer layers 118 over the semiconductor structure 100 followed by an anisotropic etching process (such as dry plasma etching). In some embodiments, the deposition process includes ALD, CVD (such as PECVD, LPCVD or HARP), another suitable technique, or a combination thereof. Vertical portions of the dielectric material left on the sidewalls of the dummy gate structures 112 serve as the gate spacer layers 118, in accordance with some embodiments. In some embodiments, the gate spacer layer 120 has a thickness T3 (in the X direction) along the sidewalls of the dummy gate structures 112. In some embodiments, the thickness T3 is in a range from about 4 nm to about 12 nm.

FIGS. 3B-1 to 3B-4 illustrate cross-sectional views of the semiconductor structure 100 after the formation of source/drain recesses 120 and inner spacer layers 122 respectively corresponding to line Y1-Y1, line Y3-Y3, line X1-X1 and line X3-X3, in accordance with some embodiments.

An etching process is performed to recess the source/drain regions of the active regions 104, thereby forming source/drain recesses 120, as shown in FIGS. 3B-1 and 3B-3, in accordance with some embodiments. The etching process may be an anisotropic etching process such as dry plasma etching, an isotropic etching process such as dry chemical etching, remote plasma etching or wet chemical etching, or a combination thereof. The gate spacer layers 118 and the dummy gate structures 112 may serve as etch masks such that the source/drain recesses 120 are formed self-aligned on opposite sides of the dummy gate structures 112, in accordance with some embodiments. In some embodiments, the etching process is performed without the need for an additional photolithography process. The source/drain recesses 120 extend a distance D1 into the lower fin elements 103N and 103P, in accordance with some embodiments. In some embodiments, the distance D1 is in a range from about 10 nm to about 50 nm.

Afterward, an etching process is performed to laterally recess, from the source/drain recesses 120, the first semiconductor layers 106 of the active regions 104, thereby forming notches, and then inner spacer layers 122 are formed in the notches, as shown in FIG. 3B-3, in accordance with some embodiments. The inner spacer layers 122 are formed to abut the recessed side surfaces of the first semiconductor layers 106, in accordance with some embodiments. In some embodiments, the inner spacer layers 122 are located between adjacent second semiconductor layers 108 and between the bottommost second semiconductor layer 108 and the lower fin element 103N (or 103P). In some embodiments, the inner spacer layers 122 extend directly below the gate spacer layers 118, in accordance with some embodiments.

The inner spacer layers 122 may avoid the source/drain features and the gate stack from being in direct contact and are configured to reduce the parasitic capacitance between the gate stack and the source/drain features (i.e., Cgs and Cgd), in accordance with some embodiments. In some embodiments, the inner spacer layers 122 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), a multilayer thereof, or a combination thereof. In some embodiments, the inner spacer layers 122 are made of low-k dielectric materials. For example, the dielectric constant (k) values of the inner spacer layers 122 may be lower than a k-value of silicon oxide (SiO), such as lower than 4.2, equal to or lower than about 3.9, such as in a range from about 3.5 to about 3.9. In some embodiments, the inner spacer layers 122 may include a porous version of an existing dielectric material or an air gap within the dielectric material to have a lower dielectric constant.

In some embodiments, the inner spacer layers 122 are formed by depositing a dielectric material for the inner spacer layers 122 over the semiconductor structure 100 to overfill the notches, and then etching back the dielectric material to remove the dielectric material outside the notches. Portions of the dielectric material left in the notches serve as the inner spacer layers 122, in accordance with some embodiments. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

In some embodiments, the dielectric constant value of the inner spacer layers 122 is greater than that of the gate spacer layers 118. In some embodiments, the inner spacer layers 122 having a relatively high dielectric constant value may increase the etching resistance in a subsequent etching process for removing the first semiconductor layers 106, and the gate spacer layers 118 having a relatively low dielectric constant value may reduce the capacitance between subsequently formed gate stacks and the frontside contact plugs. In some embodiments, the inner spacer layers 122 have thickness T4 in the X direction. In some embodiments, the thickness T4 is in a range from about 4 nm to about 12 nm.

FIGS. 3C-1 to 3C-5 illustrate cross-sectional views of the semiconductor structure 100 after the formation of sacrificial layers 124, insulating layers 126, source/drain features 128 (including 128N and 128P), a first interlayer dielectric layer 130 and fin isolation structures 134 respectively corresponding to line Y1-Y1, line Y3-Y3, line Y4-Y4, line X1-X1 and line X3-X3, in accordance with some embodiments.

Sacrificial layers 124 are formed in the source/drain recesses 120 over the lower fin elements 103N and 103P, as shown in FIGS. 3C-1 and 3C-4, in accordance with some embodiments. In some embodiments, the sacrificial layers 124 are made of an epitaxial semiconductor material such as silicon germanium or germanium, formed by MBE, MOCVD, or VPE, another suitable technique, or a combination thereof. The sacrificial layers 124 and the lower fin elements 103N and 103P are made of different materials and have a great difference in etching selectivity. In some embodiments, the sacrificial layers 124 are in direct contact with the lower fin elements 103N and 103P and the isolation structure 110.

In some embodiments, the sacrificial layers 124 are made of suitable dielectric material having etching selectivity to the lower fin elements 103N and 103P, e.g., silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN), or high-k dielectric material (e.g., with dielectric constant greater than about 7.9) such as LaO, AlO, AlON, ZrO, HfO, ZnO, ZrN, ZrAlO, TiO, TaO, YO, TaCN, or a combination thereof. In some embodiments, the sacrificial layers 124 have thickness T5 in the Z direction. In some embodiments, the thickness T5 is in a range from about 10 nm to about 50 nm. In some embodiments, the top surface of the sacrificial layers 124 may be higher than, level with, or lower than the top surface of the lower fin elements 103N and 103P.

Insulating layers 126 are formed in the source/drain recesses 120 over the sacrificial layers 124, as shown in FIGS. 3C-1 and 3C-4, in accordance with some embodiments. In some embodiments, the insulating layers 126 are in direct contact with the sacrificial layers 124 and the bottommost inner spacer layers 122. In some embodiments, the insulating layers 126 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN), or high-k dielectric material (e.g., with dielectric constant greater than about 7.9) such as LaO, AlO, AlON, ZrO, HfO, ZnO, ZrN, ZrAlO, TiO, TaO, YO, TaCN, or a combination thereof. In some embodiments, the insulating layers 126 have a great difference in etching selectivity to the lower fin elements 103N and 103P and the inner spacer layers 122.

In some embodiments, the insulating layers 126 are deposited using a technique such as ALD, CVD (such as HDP-CVD, LPCVD or PECVD), another suitable technique, or a combination thereof, followed by an etching-back process. In some embodiments, the insulating layers 126 have a thickness T6 in the Z direction. In some embodiments, the thickness T6 is in a range from about 3 nm to about 20 nm. In some embodiments, the thickness T6 of the insulating layers 126 is thinner than the thickness T5 of the sacrificial layers 124. In some embodiments, the top surfaces of the sacrificial layers 124 are level with, or lower than, the top surfaces of the bottommost inner spacer layers 122.

Source/drain features 128N and 128P are formed over the insulating layers 126 in the source/drain recesses 120, as shown in FIGS. 3C-1 and 3C-4, in accordance with some embodiments. The source/drain features 128 are formed on opposite sides of the dummy gate structures 112, in accordance with some embodiments. In some embodiments, the source/drain features 128N have a different electrically conductive type than the source/drain features 128P. The formation may include one or more epitaxial growth processes. These epitaxial growth processes may be MBE, MOCVD, or VPE, another suitable technique, or a combination thereof.

In some embodiments, the source/drain features 128N and the source/drain features 128P may be formed separately. For example, a patterned mask layer (such as a photoresist layer and/or a hard mask layer) may be formed to cover the semiconductor structure 100 over the n-type well, and then the source/drain features 128N are grown. Afterward, the patterned mask layer may be removed. Similarly, a patterned mask layer (such as a photoresist layer and/or a hard mask layer) is formed to cover the semiconductor structure 100 over the p-type well, and then the source/drain features 128P are grown. Afterward, the patterned mask layer may be removed.

In some embodiments, the source/drain features 128N and 128P are in-situ doped during the epitaxial processes. In some embodiments, the source/drain features 128N are doped with the n-type dopant during the epitaxial growth process. For example, the n-type dopant may be phosphorous (P) or arsenic (As). For example, the n-type source/drain features 128N may be the epitaxially grown silicon phosphorous (SiP), silicon carbon (SiC), silicon phosphorous carbon (SiPC), silicon phosphorous arsenic (SiPAs), silicon arsenic (SiAs), silicon (Si), or a combination thereof doped with phosphorous and/or arsenic. In some embodiments, the concentrations of the dopant (e.g., P) in the source/drain features 128N are in a range from about 2×10¹⁹ cm⁻³ to about 3×10²¹ cm⁻³.

In some embodiments, the source/drain features 128P are doped with the p-type dopant during the epitaxial growth process. For example, the p-type dopant may be boron (B) or BF₂. For example, the p-type source/drain features 128P may be the epitaxially grown silicon germanium (SiGe), silicon germanium carbon (SiGeC), germanium (Ge), silicon (P), or a combination thereof doped with boron (B). In some embodiments, the concentrations of the dopant (e.g., B) in the source/drain features 128P are in a range from about 1×10¹⁹ cm⁻³ to about 6×10²⁰ cm⁻³. In some embodiments, the n-type source/drain features 128N and the p-type source/drain features 128P are made of different epitaxial materials. For example, the n-type source/drain features 128N are made of SiP, and the p-type source/drain features 128P are made of SiGe.

A first interlayer dielectric layer 130 is formed to cover the source/drain features 128N and 128P, in accordance with some embodiments. The first interlayer dielectric layer 130 overfills the space between dummy gate structures 112, in accordance with some embodiments. In some embodiments, the first interlayer dielectric layer 130 is made of a dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), as un-doped silicate glass (USG), doped silicon oxide such as borophosphosilicate glass (BPSG), fluoride-doped silicate glass (FSG), Phosphosilicate glass (PSG), borosilicate glass (BSG), a multilayer thereof, and/or another suitable dielectric material.

In some embodiments, the dielectric material for the first interlayer dielectric layer 130 is deposited using a technique such as CVD (such as HDP-CVD, PECVD, HARP or FCVD), another suitable technique, or a combination thereof. The dielectric materials for the first interlayer dielectric layer 130 above the upper surface of the dummy gate electrode layer 116 are removed using CMP, for example, in accordance with some embodiments.

Fin isolation structures 134 are formed through the dummy gate structures 112₁, 112₄ and 112₆ and the underlying active regions 104N and 104P, as shown in FIGS. 3C-3, 3C-4 and 3E-5, in accordance with some embodiments. The fin isolation structures 134 extend at least about 5 nm into the lower fin elements 103N and 103P, in accordance with some embodiments. In some embodiments, the fin isolation structures 134 may be extend into the substrate 102 and have bottom surfaces lower than the bottom surface of the isolation structure 110.

In some embodiments, the dummy gate structures 112₁, 112₄ and 112₆ are completely replaced with the fin isolation structures 134. In some embodiments, each of the active regions 104N and 104P is cut through by the fin isolation structures 134 into several segments that are electrically isolated from one another. In some embodiments, the fin isolation structures 134 extend in the Y direction. The fin isolation structures 134 have longitudinal axes parallel to the Y direction, in accordance with some embodiments. In some embodiments, the fin isolation structures 134 are configured to prevent leakage between the neighboring cell regions C1 and C2. The fin isolation structures 134 may be also referred to as cut poly gate on oxide definition edge (CPODE) pattern.

The fin isolation structures 134 are made of a dielectric material such as silicon oxide (SiO₂), silicon oxynitride (SiON), silicon nitride (SiN), silicon carbon nitride (SiCN), silicon oxycarbonitride (SiOCN), oxygen-doped silicon carbonitride (Si(O)CN), or a combination thereof. In some embodiments, the fin isolation structures 134 include dielectric material with k-value greater than 7.9, such as LaO, AlO, AlON, ZrO, HfO, ZnO, ZrN, ZrAlO, TiO, TaO, YO, TaCN, or a combination thereof.

The formation of the fin isolation structures 134 includes patterning the dummy gate structures 112₁, 112₄ and 112₆ and the active regions 104N and 104P using photolithography and etching processes to form cutting trenches (where the fin isolation structures 134 are to be formed), depositing a dielectric material for the fin isolation structures 134 to overfill the cutting trenches, in accordance with some embodiments. The etching process may be an anisotropic etching process such as dry plasma etching, an isotropic etching process such as dry chemical etching, remote plasma etching or wet chemical etching, or a combination thereof. In some embodiments, the deposition process is ALD, CVD (such as LPCVD, PECVD, HDP-CVD, or HARP), another suitable technique, or a combination thereof. A planarization process is then performed on dielectric material formed until the dummy gate structures 112 and the first interlayer dielectric layer 130 are exposed, in accordance with some embodiments. The planarization may be CMP, etching back process, or a combination thereof.

FIGS. 3D-1 to 3D-6 illustrate cross-sectional views of the semiconductor structure 100 after the formation of final gate stacks 136 (including 136₁-136₃), dielectric capping layers 144 and gate isolation structures 146 respectively corresponding to line Y1-Y1, line Y3-Y3, line Y4-Y4, line X1-X1, line X3-X3 and line X4-X4, in accordance with some embodiments.

One or more etching processes are performed to remove the dummy gate structures 112₂, 112₃ and 112₅ to form gate trenches and remove the first semiconductor layers 106 of the active regions 104N and 104P to form gaps, in accordance with some embodiments. In some embodiments, the gate trenches expose the channel regions of the active regions 104N and 104P. In some embodiments, the gate trenches further expose the sidewalls of the gate spacer layers 118 facing the channel region. In some embodiments, the gaps expose the inner sidewalls of the inner spacer layers 122 facing the channel region. The one or more etching processes may include an anisotropic etching process such as dry plasma etching, an isotropic etching process such as dry chemical etching, remote plasma etching or wet chemical etching, or a combination thereof.

After the one or more etching processes, the four main surfaces of the second semiconductor layers 108 are exposed, in accordance with some embodiments. The exposed second semiconductor layers 108 of the active region 104N form three sets of nanostructures 108N, and the exposed second semiconductor layers 108 of the active region 104P form three sets of nanostructures 108P, as shown in FIGS. 3D-2 and 3D-4, in accordance with some embodiments. Each set includes three nanostructures 108N and 108P vertically stacked and spaced apart from one other, in accordance with some embodiments.

As the term is used herein, “nanostructures” refers to the semiconductor layers with cylindrical shape, bar shaped and/or sheet shape. The nanostructures 108N and 108P function as channels of the resulting semiconductor devices (e.g., nanostructure transistors such as GAA transistors), in accordance with some embodiments. In some embodiments, the width D2 (the dimension in the Y direction) of the nanostructures 108N and 108P is in a range from about 4 nm to about 70 nm.

Final gate stacks 136 (including 136₁ to 136₃) are formed in the gate trenches and gaps, thereby wrapping around the nanostructures 108N and 108P, as shown in FIGS. 3D-2, 3D-4 and 3D-5, in accordance with some embodiments. In some embodiments, the final gate stacks 136 extend in the Y direction. That is, the final gate stacks 136 have longitudinal axes parallel to the Y direction, in accordance with some embodiments. The final gate stacks 136 engage the channel region so that current can flow between the source/drain regions during operation.

In some embodiments, each of the final gate stacks 136 includes a gate dielectric layer 138 and a metal gate electrode layer 140, as shown in FIGS. 3D-2, 3D-4 and 3D-5, in accordance with some embodiments. The gate dielectric layer 138 is formed to wrap around the nanostructures 108N and 108P, in accordance with some embodiments. The gate dielectric layer 138 is further formed along the upper surface of the isolation structure 110, in accordance with some embodiments. The gate dielectric layer 138 is also conformally formed along the sidewalls of the gate spacer layers 118 facing the channel region, in accordance with some embodiments. The gate dielectric layer 138 is also conformally formed along the sidewalls of the inner spacer layers 122 facing the channel region, in accordance with some embodiments.

The gate dielectric layer 138 includes an interfacial layer and a high-k dielectric layer on the interfacial layer, in accordance with some embodiments. The interfacial layer is formed on the exposed surfaces of the nanostructures 108N and 108P and the exposed upper surfaces of the lower fin elements 103N and 103P, in accordance with some embodiments. In some embodiments, the interfacial layer is made of a chemically formed silicon oxide. In some embodiments, the interfacial layer is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108 and the lower fin elements 103P and 103N is oxidized to form the interfacial layer, in accordance with some embodiments.

In some embodiments, the high-k dielectric layer is dielectric material with high dielectric constant (k value), for example, greater than 7.9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), Si₃N₄, oxynitrides (SiON), a combination thereof, or another suitable material. The high-k dielectric layer may be deposited using ALD, PVD, CVD, and/or another suitable technique. In some embodiments, the high-k dielectric layer has a thickness in a range from about 0.5 nm to about 3 nm.

The metal gate electrode layer 140 is formed over the gate dielectric layer 138 and overfills the remainder of the gate trench 128 and the gaps 130, in accordance with some embodiments. In some embodiments, the metal gate electrode layer 140 is made of more than one conductive material, such as a metal, metal alloy, conductive metal oxide and/or metal nitride, another suitable conductive material, or a combination thereof. For example, the metal gate electrode layer 140 may be made of Ti, Ag, Al, TiAlN, TaC, TaCN, TaSiN, Mn, Zr, TiN, TaN, Ru, Mo, WN, Cu, W, Re, Ir, Co, Ni, Pt, another suitable conductive material, or multilayers thereof. As discussed in detail below, the metal gate electrode layer 140 may be a multi-layer structure with various combinations of a work function layer with a selected work function to enhance the device performance for the n-type transistor and the p-type transistor, a gate metal fill layer, or another suitable layer.

A planarization process such as CMP may be performed on the semiconductor structure 100 to remove the materials of the gate dielectric layer 138 and the metal gate electrode layer 140 formed above the upper surface of the first interlayer dielectric layer 130, in accordance with some embodiments. The final gate stacks 136 that are wrapped around the nanostructures 108N or 108P combine with the neighboring source/drain features 128N or 128P to form nanostructure transistors. In some embodiments, the transistors formed on the nanostructures 108N in the p-type well are the n-channel nanostructure transistors, and the transistors formed on the nanostructures 108P in the n-type well are the p-channel nanostructure transistors. In some embodiments, the neighboring transistors share a common source/drain feature 128N or 128P.

An etching process is performed to recess the final gate stacks 136 and the gate spacer layers 118 thereby forming recesses, and then dielectric cap layers 144 are formed in the recesses, as shown in FIGS. 3D-2, 3D-4 and 3D-5, in accordance with some embodiments. In some embodiments, the dielectric cap layers 144 are configured to protect the final gate stacks 136 in the etching process for forming the frontside contact plugs. The etching process may be an anisotropic etching process such as dry plasma etching, an isotropic etching process such as dry chemical etching, remote plasma etching or wet chemical etching, or a combination thereof.

In some embodiments, the dielectric cap layers 144 are made of a dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), nitride-based dielectric, metal oxide dielectric such as HfO₂, Ta₂O₅, TiO₂, ZrO₂, Al₂O₃, Y₂O₃, or a combination thereof.

In some embodiments, a dielectric material for the dielectric cap layers 144 is deposited using a technique such as ALD, CVD (such as LPCVD, PECVD, HDP-CVD, or HARP), another suitable technique, or a combination thereof. Afterward, a planarization process is performed on the dielectric material for the dielectric cap layers 144 until the first interlayer dielectric layer 130 is exposed, in accordance with some embodiments. The planarization may be CMP, etching back process, or a combination thereof. In some embodiments, the thickness of the dielectric cap layers 144 in the Z direction is in a range from about 2 nm to about 60 nm.

Gate isolation structures 146 are formed in and/or through the dielectric capping layers 144, the final gate stacks 136, the fin isolation structures 134 and the gate spacer layers 118 and land on the isolation structure 110, as shown in FIGS. 3D-2, 3D-3 and 3D-6, in accordance with some embodiments. The final gate stacks 136 are cut through by the gate isolation structures 146 into several segments, in accordance with some embodiments. In some embodiments, the final gate stacks 136 extend a distance of about 5 nm to about 60 nm into the isolation structure 110. The gate isolation structures 146 may be also referred to as cut metal gate (CMG) pattern.

The formation of the gate isolation structures 146 includes patterning the dielectric capping layers 144, the final gate stacks 136, the fin isolation structures 134 and the gate spacer layers 118 to form gate-cut openings (where the gate isolation structures 146 are to be formed) using photolithography and etching processes until the isolation structure 110 is exposed. The etch processes may include dry etching such as reactive ion etch (RIE), neutral beam etch (NBE), inductive coupled plasma (ICP) etch, capacitively coupled plasma (CCP) etch, another suitable method, or a combination thereof.

The formation of the gate isolation structures 146 further includes depositing a dielectric material for the gate isolation structures 146 to overfill the gate-cut opening, in accordance with some embodiments. The gate isolation structures 146 are made of a dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the gate isolation structures 146 include dielectric material with dielectric constant value greater than 7.9, such as LaO, AlO, AlON, ZrO, HfO, ZnO, ZrN, ZrAlO, TiO, TaO, YO, TaCN, or a combination thereof. In some embodiments, the deposition process is ALD, CVD (such as LPCVD, PECVD, HDP-CVD, or HARP), another suitable technique, or a combination thereof. Afterward, a planarization process is then performed on the dielectric material for the gate isolation structures 146 until the dielectric capping layer 144 and the first interlayer dielectric layer 130 are exposed, in accordance with some embodiments. The planarization may be CMP, etching back process, or a combination thereof.

FIGS. 3E-1 to 3E-8 illustrate cross-sectional views of the semiconductor structure 100 after the formation of frontside contact plugs 148 (including 148A and 148B), a second interlayer dielectric layer 152, vias 154 (including 154A, 154B and 154C), an intermetal dielectric layer 156 and a frontside first metal layer (F_M1) respectively corresponding to line Y1-Y1, line Y2-Y2, line Y3-Y3, line Y4-Y4, line X1-X1, line X2-X2, line X3-X3 and line X4-X4, in accordance with some embodiments.

Frontside contact plugs 148A and 148B are formed in and/or through the first interlayer dielectric layer 130, as shown in FIGS. 3E-1, 3E-2, 3E-5, 3E-6, 3E-7 and 3E-8, in accordance with some embodiments. Frontside contact plugs 148A and 148B land on the source/drain features 128N and 128P, in accordance with some embodiments. The contact plugs 148A are electrically connected to subsequently formed power supply lines and may also serve as Vdd/Vss nodes of the integrated circuits of the cell regions C1 and C2, in accordance with some embodiments. The contact plugs 148B are electrically connected to subsequently formed signal lines and may also serve as non-Vdd/Vss nodes of the integrated circuits of the cell regions C1 and C2. In some embodiments, the contact plugs 148A and 148B extend in the Y direction.

In some embodiments, the formation of the contact plugs 148 includes patterning the first interlayer dielectric layer 130 to form contact openings (where the contact plugs 148 are to be formed) using photolithography and etching processes until the source/drain features 128N and 128P are exposed. The etch process may include dry etching such as RIE, NBE, ICP etch, CCP etch, another suitable method, or a combination thereof. In some embodiments, the sidewalls of the gate spacer layers 118 are exposed from the contact openings.

Silicide layers 150 are formed on the exposed surfaces of the source/drain features 128N and 128P. In some embodiments, the silicide layers 150 are made of WSi, NiSi, TiSi and/or CoSi. In some embodiments, the formation of the silicide layers 150 includes depositing a metal material followed by one or more annealing processes. The semiconductive material (e.g., Si) from the source/drain features 128N and 128P reacts with the metal material to form the silicide layers 150, in accordance with some embodiments.

Afterward, one or more conductive materials for the contact plugs 148 are deposited to overfill the contact openings, in accordance with some embodiments. In some embodiments, one or more conductive materials are deposited using CVD, PVD, e-beam evaporation, ALD, electroplating (ECP), electroless deposition (ELD), another suitable method, or a combination thereof to overfill the contact openings. The one or more conductive materials over the upper surface of the first interlayer dielectric layer 130 are planarized using, for example, CMP. After the planarization process, the upper surfaces of the contact plugs 148, first interlayer dielectric layer 130, the fin isolation structures 134, the dielectric capping layers 144 and the gate isolation structures 146 are substantially coplanar, in accordance with some embodiments. In some embodiments, the contact plugs 148 are in contact with the sidewalls of the gate spacer layers 118.

The contact plugs 148 may have a multilayer structure including, for example, lining layers, barrier/adhesive layers, seed layers, metal bulk layers, another suitable layer, or a combination thereof. For example, a barrier/adhesive layer (not shown) may optionally be deposited along the sidewalls and the bottom surfaces of the contact openings. The barrier/adhesive layer is used to prevent the metal from the subsequently formed metal material from diffusing into the dielectric material (e.g., the first interlayer dielectric layer 130) and/or to improve adhesion between the subsequently formed metal material and the dielectric material (e.g., the first interlayer dielectric layer 130. The barrier/adhesive layer may be made of tantalum (Ta), tantalum nitride (TaN), titanium (Ti), titanium nitride (TiN), cobalt tungsten (CoW), another suitable material, or a combination thereof. If the subsequently formed metal material does not easily diffuse into the dielectric material, the barrier layer may be omitted.

A metal bulk layer is then deposited on the barrier/adhesive layer (if formed) to fill the remainder of the contact openings. In some embodiments, the metal bulk layer is formed using a selective deposition technique such as cyclic CVD process or ELD process, and it is not necessary to form an adhesive layer in the contact openings before depositing the metal bulk material. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

A second interlayer dielectric layer 152 is formed over the semiconductor structure 100, as shown in FIGS. 3E-1 to 3E-8, in accordance with some embodiments. In some embodiments, the second interlayer dielectric layer 152 is made of a dielectric material, such as USG, BPSG, FSG, PSG, BSG, and/or another suitable dielectric material. In some embodiments, the second interlayer dielectric layer 152 is deposited using a technique such as CVD (such as HDP-CVD, PECVD, HARP or FCVD), another suitable technique, or a combination thereof.

Vias 154A and 154B are formed in and/or through the second interlayer dielectric layer 152 and land on the contact plugs 148A and 148B, and vias 154C are formed in and/or through the second interlayer dielectric layer 152 and the dielectric capping layer 144 and land on the metal gate electrode layers 140 of the final gate stacks 136, as shown in FIGS. 3E-1 to 3E-8, in accordance with some embodiments. The vias 154A and 154B are electrically connected to source/drain terminals of the nanostructure transistors through the contact plugs 148A and 148B, and may be also referred to as source/drain vias (VS or VD), in accordance with some embodiments. The vias 154C are electrically connected to the metal gate electrode layers 140 of the final gate stacks 136, and may be also referred to as gate vias (VG), in accordance with some embodiments.

In some embodiments, the formation of the vias 154A, 154B and 154C includes patterning the second interlayer dielectric layer 152 and the dielectric capping layer 144 to form via openings (where the vias 154A, 154B and 154C are to be formed) using photolithography and etching processes. In some embodiments, the final gate stacks 136 are exposed from the via openings for the vias 154C, and the contact plugs 148A and 148B are exposed from the via openings for the vias 154A and 154B. The etch processes may include dry etching such as RIE, NBE, ICP etch, CCP etch, another suitable method, or a combination thereof. In some embodiments, the patterning processes for the vias 154A, the vias 154B and the via 154C may be formed separately. Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the second interlayer dielectric layer 152 are planarized using, for example, CMP. After the planarization process, the upper surfaces of the vias 154A, 154B and 154C and the upper surface of the second interlayer dielectric layer 152 are substantially coplanar, in accordance with some embodiments.

The vias 154A, 154B and 154C may have a multilayer structure. For example, a barrier/adhesive layer (not shown) may optionally be deposited along the sidewalls and the bottom surfaces of the via openings. The barrier layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the via openings. In some embodiments, the metal bulk layers are made of one or more conductive materials, such as cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), or a combination thereof.

An intermetal dielectric layer 156 is formed over the vias 154A, 154B and 154C and the second interlayer dielectric layer 152, as shown in FIGS. 3E-1 to 3E-8, in accordance with some embodiments. In some embodiments, the intermetal dielectric layer 156 is made of one or more dielectric materials, such as silicon oxide (SiO), silicon nitride (SiN), silicon oxynitride (SiON), silicon carbide (SiC), aluminum oxide (Al₂O₃), dielectric material(s) with low dielectric constant (low-k) such as SiCOH, SiOCN, and/or SiOC, or a combination thereof. In some embodiments, the intermetal dielectric layer 156 is made of an extreme low-k (ELK) dielectric material with a dielectric constant (k) less than about 3.0, or even less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon oxide (SiO₂). In some embodiments, the intermetal dielectric layer 156 is formed using CVD (such as LPCVD, HARP, and FCVD), ALD, spin-on coating, another suitable method, or a combination thereof. A post-curing process (e.g., UV curing) may be performed on the as-deposited ELK dielectric material for the intermetal dielectric layer 156 to form a porous structure.

A frontside first metal layer (F_M1) is formed in and/or through the intermetal dielectric layer 156, in accordance with some embodiments. The frontside first metal layer (F_M1) includes several lines (tracks) e.g., power supply lines 158A and signal lines 158B, as shown in FIGS. 3E-1 to 3E-8, in accordance with some embodiments. The power supply lines 158A include a Vdd frontside power rail providing positive voltage and a Vss frontside power rail which may be an electrical ground, in accordance with some embodiments. The signal lines 158B are configured for signal transmission and are electrically isolated from the power supply lines 158A, in accordance with some embodiments. In some embodiments, the maximum number of the signal lines 158B arranged in parallel in an STD cell (e.g., the cell region C1) is four, as shown in FIGS. 2A, 3G-2 and 3G-3.

The lines 158A and 158B extend in the X direction, in accordance with some embodiments. That is, the lines 158A and 158B have longitudinal axes parallel to the X direction, in accordance with some embodiments. The Vss power rail is electrically connected to the Vss node (e.g., source terminals) of the n-channel transistors through the vias 154A and the contact plugs 148A, in accordance with some embodiments. The Vdd power rail is electrically connected to the Vdd node (e.g., source terminals) of the p-channel transistors through the vias 154A and the contact plugs 148A, in accordance with some embodiments. The signal lines 158B are electrically connected to the final gate stacks 136 through the vias 154C, and electrically connected to the non-Vdd/Vss nodes (e.g., drain terminals) of the n-channel transistors and p-channel transistors and vias 154B and the contact plugs 148B, in accordance with some embodiments.

In some embodiments, the formation of the frontside first metal layer (F_M1) includes patterning the intermetal dielectric layer 156 using photolithography and etching processes to form trenches (where the frontside first metal layer (F_M1) is to be formed) through the intermetal dielectric layer 156 and exposing the vias 154A, 154B and 154C. The etch processes may include dry etching such as RIE, NBE, ICP etch, CCP etch, another suitable method, or a combination thereof. One or more conductive materials for the frontside first metal layer (F_M1) are then deposited using CVD, PVD, e-beam evaporation, ALD, ECP, ELD, another suitable method to overfill the trenches. Afterward, a planarization process such as CMP and/or an etching back process is performed to remove an excess portion of the conductive materials from the upper surface of the intermetal dielectric layer 156. After the planarization process, the upper surfaces of the frontside first metal layer (F_M1) and the intermetal dielectric layer 156 are substantially coplanar, in accordance with some embodiments.

The frontside first metal layer (F_M1) may have a multilayer structure. For example, a barrier/adhesive layer (not shown) may optionally be deposited along the sidewalls and the bottom surfaces of the trenches. The barrier layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the trenches. In some embodiments, the metal bulk layers are made of one or more conductive materials, such as cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

The semiconductor structure 100 may undergo further frontside BEOL processes to form various interconnection conductive features (not shown) over the semiconductor structure 100, such as frontside second metal layer (F_M2) to frontside tenth metal layer (F_M10) and vias between neighboring two metal layers.

FIGS. 3F-1 to 3F-4 illustrate cross-sectional views of the semiconductor structure 100 after the formation of contact openings 160 respectively corresponding to line Y1-Y1, line Y2-Y2, line X1-X1 and line X2-X2, in accordance with some embodiments.

The semiconductor structure 100 is flipped upside down, as shown FIGS. 3F-1 to 3F-4, in accordance with some embodiments. In some embodiments, a carrier substrate (not shown) may be formed over and seal the frontside of the semiconductor structure 100 before flipping the semiconductor structure 100 to protect of components of the semiconductor structure 100 during subsequent backside processes. After flipping the semiconductor structure 100, the backside surface of the substrate 102 (the backside of the semiconductor structure 100) faces upward, in accordance with some embodiments.

The substrate 102 is removed from the backside of the semiconductor structure 100 using a planarization process such as CMP, an etching process, or a combination thereof until the lower fin elements 103N and 103P, the isolation structure 110 and the fin isolation structure 134 are exposed, as shown in FIGS. 3F-1 to 3F-4, in accordance with some embodiments. In some embodiments, the lower fin elements 103N and 103P may be also thinned down in the removal process. In some embodiments, after the removal process, the lower fin elements 103N and 103P have thickness T7 in a range from about 5 nm to about 100 nm.

A patterning process is performed on the lower fin elements 103N and 103P, the sacrificial layers 124 and the insulating layers 126 to form contact openings 160 using photolithography and etching processes, as shown in FIGS. 3F-1, 3F-3 and 3F-4, in accordance with some embodiments. The patterning process includes forming a patterned mask layer 161 over the lower fin elements 103N and 103P, the isolation structure 110 and the fin isolation structures 134, in accordance with some embodiments. The patterned mask layer 161 has opening patterns which expose the lower fin elements 103N and 103P and correspond to the source/drain features 128N and 128P used for the Vdd/Vss nodes of the integrated circuits, in accordance with some embodiments. In some embodiments, the opening patterns have a dimension D3 in the X direction, as shown in FIGS. 3F-3 and 3F-4.

In some embodiments, the dimension D3 of the opening patterns is greater than the dimension D4 of the source/drain features 128N or 128P in the X direction, as shown in FIGS. 3F-3 and 3F-4. In some embodiments, the dimension D3 is in a range from about 10 nm to about 40 nm. In some embodiments, the vertical extension lines of the edges of the opening patterns pass through the inner spacer layers 122 and the gate spacer layers 118. In some embodiments, the opening patterns have a dimension D5 in the Y direction, as shown in FIG. 3F-1. The dimension D5 of the opening patterns is equal to or greater than the dimension D6 of the source/drain features 128N or 128P (or the sacrificial layers 124) in the Y direction. In some embodiments, the dimensions D5 and D6 are in a range from about 8 nm to about 20 nm.

In some embodiments, the patterned mask layer 161 is a patterned photoresist layer. For example, a photoresist may be formed over the backside of the semiconductor structure 100 such as by using spin-on coating, and patterned by exposing the photoresist to light using an appropriate photomask. Exposed or unexposed portions of the photoresist may be removed depending on whether a positive or negative resist is used. In alternative embodiments, the patterned mask layer 161 is a patterned hard mask layer. The patterned mask layer 161 may be made of metal oxide (e.g., AlO, TiO, LaO, HfO, etc.), a nitrogen-free anti-reflection layer (NFARL), carbon-doped silicon dioxide (e.g., SiO₂:C), titanium nitride (TiN), boron nitride (BN), a multilayer thereof, another suitable material, or a combination thereof. For example, a material for the patterned mask layer 161 is deposited, and a patterned photoresist layer may be formed over the material for the patterned mask layer 161 using the photolithography process described above. The material for the patterned mask layer 161 may be etched using the patterned photoresist layer to form the patterned mask layer.

The patterning process also includes performing an etching process using the patterned mask layer 161 to remove the lower fin elements 103N and 103P, the sacrificial layers 124 and the insulating layers 126 exposed from the opening patterns, thereby forming the contact openings 160, in accordance with some embodiments. The etch process may include dry etching such as RIE, NBE, ICP etch, CCP etch, another suitable method, or a combination thereof. After the etching process, the patterned mask layer 161 is removed using an etching process, an ashing process, or another suitable technique.

The etching process includes three steps, in accordance with some embodiments. The first step of the etching process removes the lower fin elements 103N and 103P (e.g., Si) until the sacrificial layers 124 are exposed, in accordance with some embodiments. The second step of the etching process removes the sacrificial layers 124 (e.g., SiGe or Ge) until the insulating layers 126 are exposed, in accordance with some embodiments. The third step of the etching process removes the insulating layers 126 (e.g., SiO) until the source/drain features 128N and 128P are exposed, in accordance with some embodiments. The first, second and third steps are performed with different processing parameters, e.g., etching precursors, RF powers, gas flow rate, etc.

Because the sacrificial layers 124 and the lower fin elements 103N and 103P have a great difference in etching selectivity, the lower fin elements 103N and 103P are consumed little or nothing in the second step of the etching process, in accordance with some embodiments. Because the insulating layers 126 have a great difference in etching selectivity to the lower fin elements 103N and 103P and the inner spacer layers 122, the lower fin elements 103N and 103P and the inner spacer layers 122 are consumed little or nothing in the third step of the etching process, in accordance with some embodiments.

The contact openings 160 are formed to have wider portions 160A and narrower portions 160B below the wider portion 160A, in accordance with some embodiments. In the X direction, the width W1 of the narrower portions 160B is narrower than the width W2 of the wider portions 160A. The opening patterns of the patterned mask layer 161 are transferred to the wider portions 160A, and thus the width W2 of the wider portions 160A is substantially the same as the dimension D3 of the opening patterns, in accordance with some embodiments. Due to the great etching selectivity between the sacrificial layers 124 and the lower fin elements 103N and 103P, the narrower portions 160B are formed self-aligned to the sacrificial layers 124 and the source/drain features 128N and 128P, and thus the width W1 of the narrower portions 160B is substantially the same as the dimension D4 of the source/drain features 128N and 128P. In some embodiments, the topmost inner spacer layers 122 (i.e., the bottommost one when the frontside of the semiconductor structure 100 faces upward) are exposed from the narrower portions 160B of the contact openings 160.

In some embodiments, the width W1 is in a range from about 8 nm to about 20 nm. In some embodiments, the width W2 is in a range from about 10 nm to about 40 nm. In some embodiments, the ratio (W2/W1) of the width W2 to the width W1 is in a range from about 1.15 to about 5, e.g., in a range from about 1.3 to about 3.

In some embodiments, the vertical extension lines of the edges (sidewalls) of the wider portions 160A pass through the inner spacer layers 122 and the gate spacer layers 118. In some embodiments, the sidewalls of the narrower portions 160B and the sidewalls of the wider portions 160A are not continuous, and the sidewalls of the narrower portions 160B indented by a distance D7 from the sidewalls of the wider portions 160A. The distance D7 is greater than 2 nm, e.g., in a range from about 2 nm to about 10 nm. In some embodiments, the connecting surface between the sidewalls of the narrower portions 160B and the sidewalls of the wider portions 160A extends horizontally in the X direction.

As a result, the contact openings 160 have T-shaped profiles, in accordance with some embodiments. The wider portions 160A of the contact openings 160 may be helpful in reducing the resistance of backside contact plugs, thereby improving the RC delay of the metal conductors (e.g., metal lines) and the IR voltage drop of the power supply. The narrower portions 160B of the contact openings 160 may be kept at a great distance from the final gate stack 136, thereby reducing the parasitic capacitance between the backside contact plugs and the final gate stack 136.

FIGS. 3G-1 to 3G-8 illustrate cross-sectional views of the semiconductor structure 100 after the formation of backside contact plugs 164, an intermetal dielectric layer 168, and a backside first metal layer (B_M1) respectively corresponding to line Y1-Y1, line Y2-Y2, line Y3-Y3, line Y4-Y4, line X1-X1, line X2-X2, line X3-X3 and line X4-X4, in accordance with some embodiments. It should be noted that FIGS. 3G-1 to 3G-8 illustrate that after the completion of backside BEOL processes, the semiconductor structure 100 is flipped upside down. That is, the frontside of the semiconductor structure 100 faces upward, in accordance with some embodiments.

Silicide layers 166 are formed on the backside surfaces of the source/drain features 128N and 128P exposed the contact openings 160, as shown in FIGS. 3G-1, 3G-5 and 3G-6, in accordance with some embodiments. In some embodiments, the silicide layers 166 are made of WSi, NiSi, TiSi and/or CoSi. In some embodiments, the formation of the silicide layers 166 includes depositing a metal material followed by one or more annealing processes. The semiconductive material (e.g., Si) from the source/drain features 128N and 128P reacts with the metal material to form the silicide layers 166, in accordance with some embodiments.

Backside contact plugs 164 are then formed on the silicide layers 166 in the contact openings 160, as shown in FIGS. 3G-1, 3G-5 and 3G-6, in accordance with some embodiments. Backside contact plugs 164 land on the source/drain features 128N and 128P, in accordance with some embodiments. The contact plugs 164 are electrically connected to subsequently formed power supply lines and may also serve as Vdd/Vss nodes of the integrated circuits of the cell regions C1 and C2, in accordance with some embodiments.

In some embodiments, the formation of the contact plugs 164 includes depositing one or more conductive materials for the contact plugs 164 are deposited to overfill the contact openings 160, in accordance with some embodiments. In some embodiments, one or more conductive materials are deposited using CVD, PVD, e-beam evaporation, ALD, ECP, ELD, another suitable method, or a combination thereof to overfill the contact openings 160. The one or more conductive materials are planarized using, for example, CMP until the isolation structure 110 and the lower fin elements 103N and 103P are exposed. In some embodiments, the backside contact plugs 164 are in contact with the isolation structure 110, the bottommost inner spacer layers 122 and the lower fin elements 103N and 103P.

The contact plugs 164 may have a multilayer structure. For example, a barrier/adhesive layer (not shown) may optionally be deposited along the sidewalls and the bottom surfaces of the contact openings 160. The barrier layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the contact openings 160. In some embodiments, the metal bulk layers are made of one or more conductive materials, such as cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), or a combination thereof.

The contact plugs 164 have wider portions 164A and narrower portions 164B, in accordance with some embodiments. In the X direction, the width W1 of the narrower portions 164B is narrower than the width W2 of the wider portions 164A. In some embodiments, in the X direction, the width W1 of the narrower portions 164B of the backside contact plug 164 is substantially equal to the width of the frontside contact plug 148A and the width D4 of the source/drain features 128N and 128P. In some embodiments, in the X direction, the width W2 of the wider portions 164A of the backside contact plug 164 is greater than the width of the frontside contact plug 148A, as shown in FIGS. 3G-5 and 3G-6.

In some embodiments, the width W1 is in a range from about 8 nm to about 20 nm. In some embodiments, the width W2 is in a range from about 10 nm to about 40 nm. In some embodiments, the ratio (W2/W1) of the width W2 to the width W1 is in a range from about 1.15 to about 3. In some embodiments, in the Y direction, the backside contact plugs 164 are shorter than the frontside contact plugs 148A, as shown in FIG. 3G-1.

In some embodiments, the vertical extension lines of the edges (sidewalls) of the wider portions 164A pass through the inner spacer layers 122 and the gate spacer layers 118. In some embodiments, the sidewalls of the narrower portions 164B and the sidewalls of the wider portions 164A are not continuous, and the sidewalls of the narrower portions 164B indented by a distance D7 from the sidewalls of the wider portions 164A. The distance D7 is greater than 2 nm, e.g., in a range from about 2 nm to about 10 nm. In some embodiments, the connecting surface between the sidewalls of the narrower portions 164B and the sidewalls of the wider portions 164A extends horizontally in the X direction. The contact plugs 164 have inverted T-shaped profiles (when the frontside of the semiconductor structure 100 faces upwards), in accordance with some embodiments.

The wider portions 164A of the contact plugs 164 may be helpful in reducing their resistance, thereby further improving the RC delay of the metal conductors (e.g., metal lines) and the IR voltage drop of the power supply. Therefore, the performance (e.g., speed) of the resulting semiconductor devices may improve. In addition, the narrower portions 164B of the contact plugs 164 may be kept at a great distance (e.g., substantially equal to the thickness T4 of the inner spacer layers 122) from the final gate stack 136, thereby reducing the parasitic capacitance between the backside contact plugs 164 and the final gate stack 136. Therefore, the continued scaling of the contact-to-poly pitch (CPP) may not be limited by the process window of the photobiography process for forming the backside contact plug, which may facilitate scaling down the semiconductor devices.

An intermetal dielectric layer 168 is formed over the backside contact plugs 164, the lower fin elements 103N and 103P and the isolation structure 110, as shown in FIGs. shown in FIGS. 3G-1 to 3G-4 and 3G-7, in accordance with some embodiments. In some embodiments, the intermetal dielectric layer 168 is made of one or more dielectric materials, such as silicon oxide (SiO), silicon nitride (SiN), silicon oxynitride (SiON), silicon carbide (SiC), aluminum oxide (Al₂O₃), dielectric material(s) with low dielectric constant (low-k) such as SiCOH, SiOCN, and/or SiOC, or a combination thereof. In some embodiments, the intermetal dielectric layer 168 is made of an extreme low-k (ELK) dielectric material with a dielectric constant (k) less than about 3.0, or even less than about 2.5. In some embodiments, ELK dielectric materials include carbon doped silicon oxide, amorphous fluorinated carbon, parylene, BCB, PTFE (Teflon), or silicon oxycarbide polymers (SiOC). In some embodiments, ELK dielectric materials include a porous version of an existing dielectric material, such as HSQ, porous MSQ, porous PAE, porous SiLK, or porous silicon oxide (SiO₂). In some embodiments, the intermetal dielectric layer 168 is formed using CVD (such as LPCVD, HARP, and FCVD), ALD, spin-on coating, another suitable method, or a combination thereof. A post-curing process (e.g., UV curing) may be performed on the as-deposited ELK dielectric material for the intermetal dielectric layer 168 to form a porous structure.

A backside first metal layer (B_M1) is formed in and/or through the intermetal dielectric layer 158, in accordance with some embodiments. The backside first metal layer (B_M1) includes power supply lines 170, shown in FIGS. 3G-1 to 3G-6 and 3G-8, in accordance with some embodiments. The power supply lines 170 include a Vdd backside power rail providing positive voltage and a Vss backside power rail which may be an electrical ground, in accordance with some embodiments.

The power supply lines 170 extend in the X direction. That is, the power supply lines 170 have longitudinal axes parallel to the X direction, in accordance with some embodiments. In some embodiments, in the Y direction, the backside power supply lines 170 is wider than the frontside power supply lines 158A, as shown in FIGS. 3G-1 to 3G-4. In some embodiments, the power supply lines 170 are in contact with the backside contact plugs 164, the lower fin elements 103N and 103P, the fin isolation structure 134 and the isolation structure 110.

The Vss backside power rail is electrically connected to the Vss node (e.g., source terminals) of the n-channel transistors through the contact plugs 164, in accordance with some embodiments. The Vdd backside power rail is electrically connected to the Vdd node (e.g., source terminals) of the p-channel transistors through the contact plugs 164, in accordance with some embodiments. In some embodiments, the insulating layers 126 are configured to electrically isolate the non-Vdd/Vss nodes (e.g., drain terminals) of the integrated circuits of the cell regions C1 and C2 from the power supply lines 170, as shown in FIG. 3G-2.

In some embodiments, the formation of the backside first metal layer (B_M1) includes patterning the intermetal dielectric layer 168 using photolithography and etching processes to form trenches (where the backside first metal layer (B_M1) is to be formed) through the intermetal dielectric layer 168 and exposing the contact plugs 164. The etch processes may include dry etching such as RIE, NBE, ICP etch, CCP etch, another suitable method, or a combination thereof. One or more conductive materials for the backside first metal layer (B_M1) are then deposited using CVD, PVD, e-beam evaporation, ALD, ECP, ELD, another suitable method to overfill the trenches. Afterward, a planarization process such as CMP and/or an etching back process is performed to remove an excess portion of the conductive materials from the upper surface of the intermetal dielectric layer 168.

The backside first metal layer (B_M1) may have a multilayer structure. For example, a barrier/adhesive layer (not shown) may optionally be deposited along the sidewalls and the bottom surfaces of the trenches. The barrier layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the trenches. In some embodiments, the metal bulk layers are made of one or more conductive materials, such as cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

The semiconductor structure 100 may undergo further backside BEOL processes to form various interconnection conductive features (not shown) over backside of the semiconductor structure 100, such as backside second metal layer (B_M2) to backside eighth metal layer (B_M8), vias between neighboring two metal layers, passivation layers, bump pads, etc.

FIGS. 4-1 and 4-2 are a modification of the semiconductor structure 100 of FIGS. 3G-5 and 3G-6, in accordance with some embodiments of the disclosure. FIGS. 4-1 and 4-2 correspond to line X1-X1 and line X2-X2, respectively. The embodiments of FIGS. 4-1 and 4-2 are similar to the embodiments of FIGS. 3A-1 and 3G-8, except that the fin isolation structures 134 do not entirely extend through the lower fin elements 103N and 103P.

In the steps for removing the substrate 102 (described above in FIGS. 3F-1 to 3F-4), the fin isolation structures 134 are not exposed and remain surrounded by the lower fin elements 103N and 103P, in accordance with some embodiments. As a result, the power supply lines 170 are spaced apart from the fin isolation structure 134 by the lower fin elements 103N and 103P, in accordance with some embodiments.

FIGS. 5-1 to 5-8 are a modification of the semiconductor structure 100 of FIGS. 3G-1 and 3G-8, in accordance with some embodiments of the disclosure. FIGS. 5-1 to 5-8 correspond to line Y1-Y1, line Y2-Y2, line Y3-Y3, line Y4-Y4, line X1-X1, line X2-X2, line X3-X3 and line X4-X4, respectively. The embodiments of FIGS. 5-1 to 5-8 are similar to the embodiments of FIGS. 3A-1 and 3G-8, except that a third interlayer dielectric layer 202 is formed before the backside contact plugs 164.

After the substrate 102 is removed described above in FIGS. 3F-1 to 3F-4, a third interlayer dielectric layer 202 is formed over the semiconductor structure 100, in accordance with some embodiments. In some embodiments, the third interlayer dielectric layer 202 is made of a dielectric material, such as USG, BPSG, FSG, PSG, BSG, and/or another suitable dielectric material. In some embodiments, the third interlayer dielectric layer 202 is deposited using a technique such as CVD (such as HDP-CVD, PECVD, HARP or FCVD), another suitable technique, or a combination thereof. In some embodiments, the third interlayer dielectric layer 202 has a thickness in a range from about 3 nm to about 100 nm.

The backside contact openings (not shown) are then formed through the intermetal third interlayer dielectric layer 202, the lower fin elements 103N and 103P, the sacrificial layers 124 and the insulating layers 126, and the backside contact plugs 164 are formed in the contact openings, in accordance with some embodiments. The interlayer dielectric layer 202 is configured to electrically isolated the lower fin elements 103N and 103P from the power supply lines 170, and thus the electrical isolation between the non-Vdd/Vss nodes of the integrated circuits and the power supply lines 170 may be further improved.

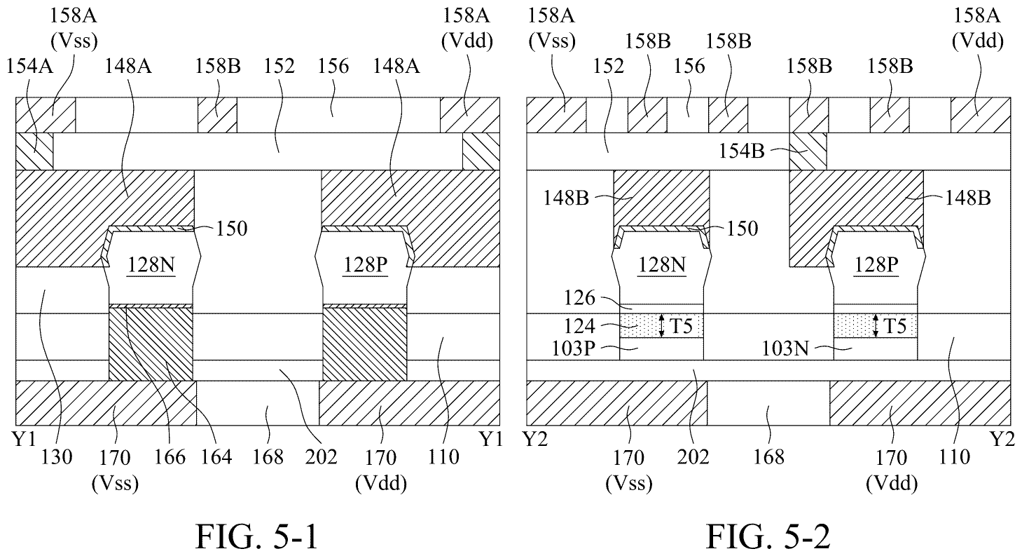

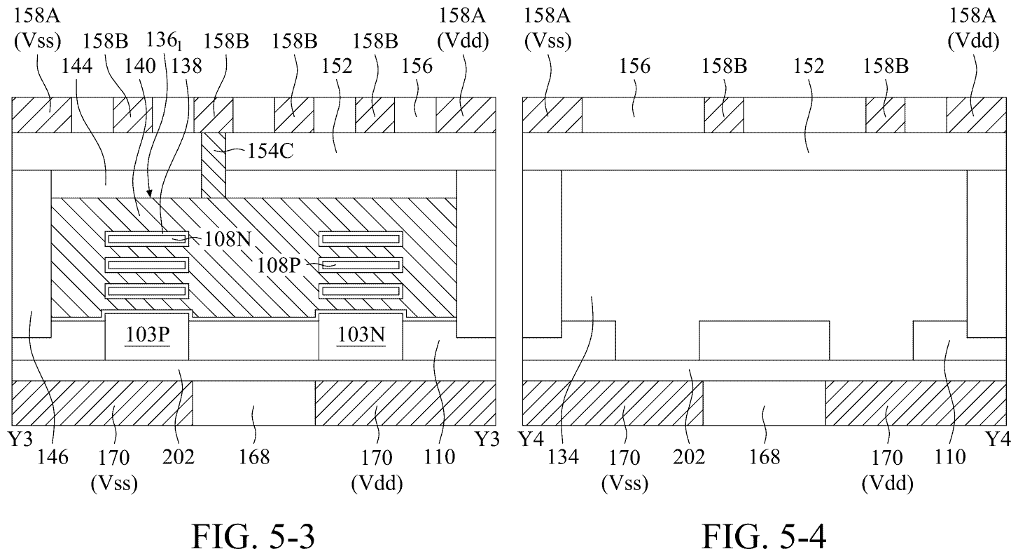

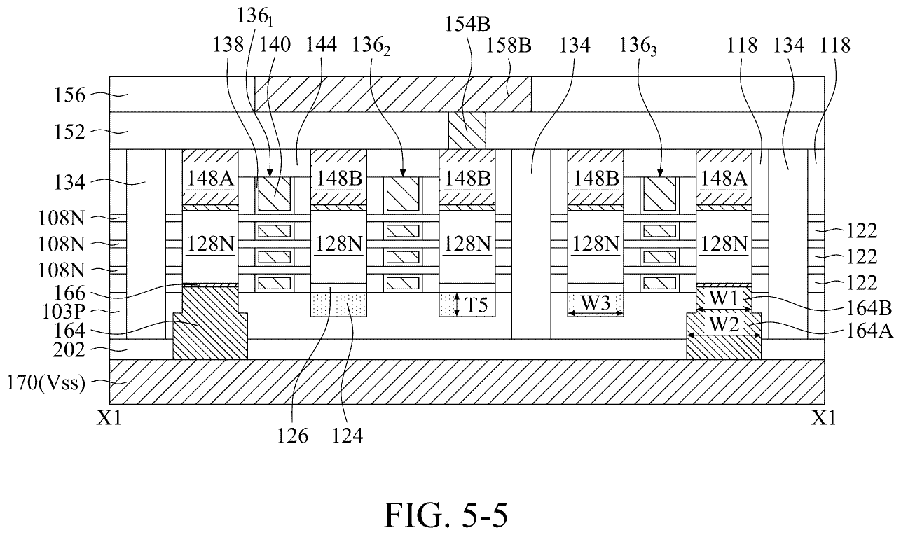

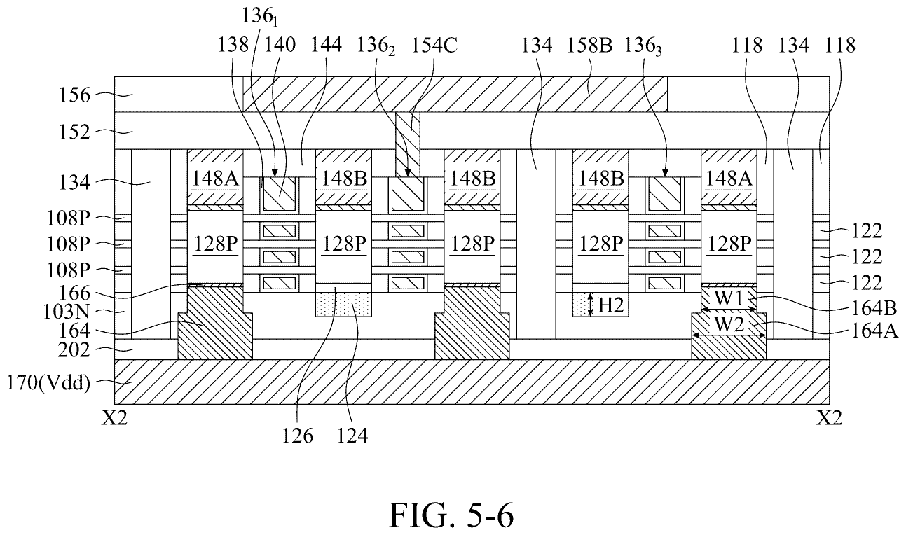

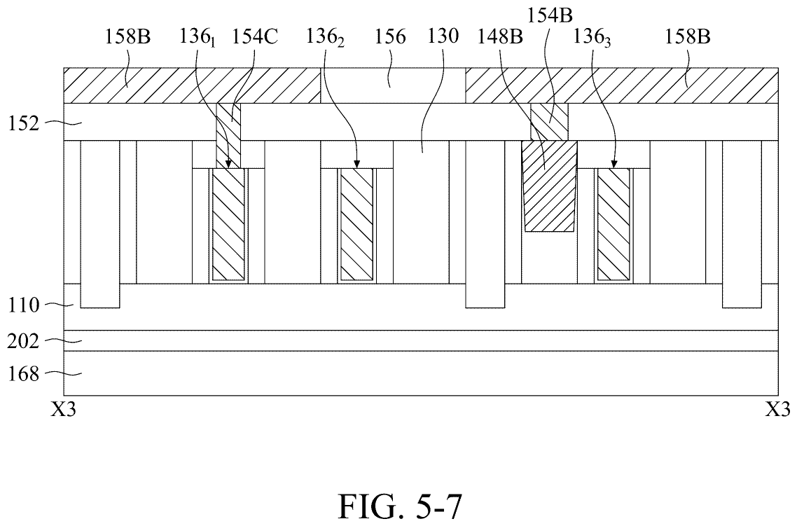

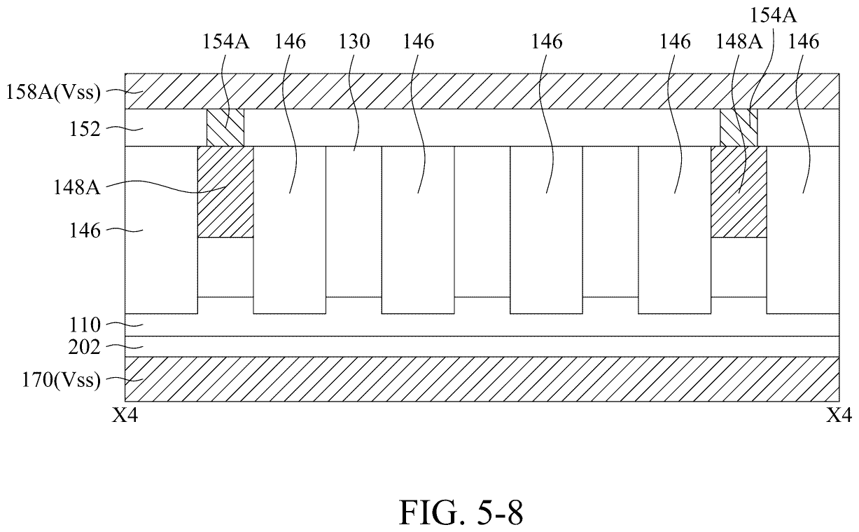

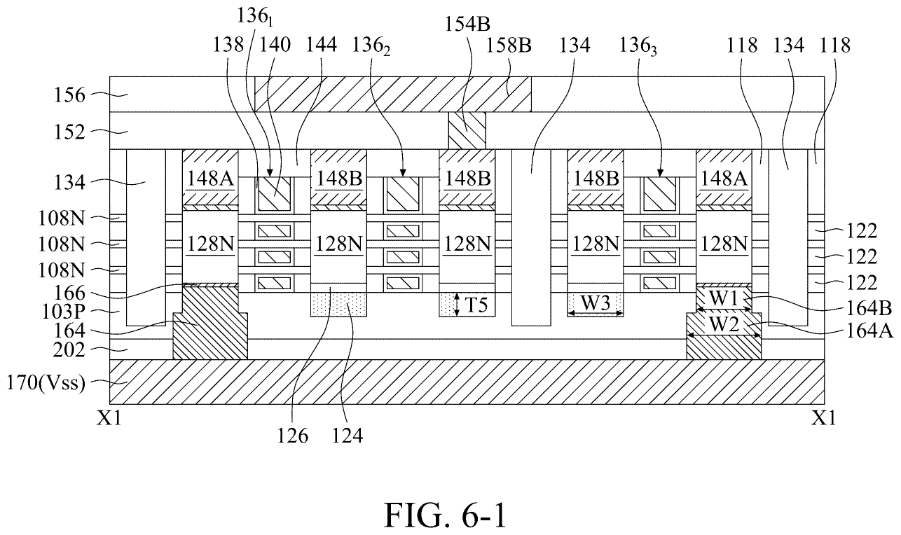

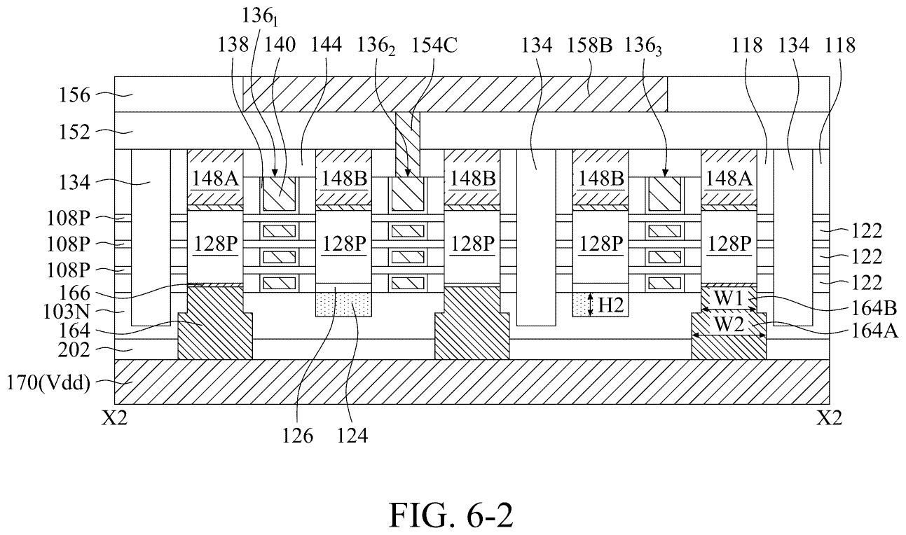

FIGS. 6-1 and 6-2 are a modification of the semiconductor structure 100 of FIGS. 5-5 and 5-6, in accordance with some embodiments of the disclosure. FIGS. 6-1 and 6-2 correspond to line X1-X1 and line X2-X2, respectively. The embodiments of FIGS. 6-1 and 6-2 are similar to the embodiments of FIGS. 5-1 and 5-2, except that the fin isolation structures 134 do not entirely extend through the lower fin elements 103N and 103P.

In the steps for removing the substrate 102 (described above in FIGS. 3F-1 to 3F-4), the fin isolation structures 134 are not exposed and remain surrounded by the lower fin elements 103N and 103P, in accordance with some embodiments. As a result, the third interlayer dielectric layer 202 is spaced apart from the fin isolation structure 134 by the lower fin elements 103N and 103P, in accordance with some embodiments.

FIGS. 7-1 and 7-2 are a modification of the semiconductor structure 100 of FIGS. 3-5 and 3-6, in accordance with some embodiments of the disclosure. FIGS. 7-1 and 7-2 correspond to line X1-X1 and line X2-X2, respectively. The embodiments of FIGS. 7-1 and 7-2 are similar to the embodiments of FIGS. 3A-1 to 3A-8, except that the silicide layers 166 are further formed on the exposed surface of the lower fin elements 103N and 103P.

During the annealing process for forming the silicide layers 166, the semiconductive material (e.g., Si) from the lower fin elements 103N and 103P may also react with the metal material, in accordance with some embodiments. As a result, the silicide layers 166 are further formed on the sidewalls of the lower fin elements 103N and 103P exposed from the contact openings 160, in accordance with some embodiments. The backside contact plugs 164 are surrounded by the silicide layers 166, in accordance with some embodiments.

FIGS. 8-1, 8-2, 8-3 and 8-4 are a modification of the semiconductor structure 100 of FIGS. 5-1, 5-2, 5-5 and 5-6, in accordance with some embodiments of the disclosure. FIGS. 8-1, 8-2, 8-3 and 8-4 correspond to line X1-X1, line X2-X2, line Y1-Y1 and line Y2-Y2, respectively. The embodiments of FIGS. 8-1 to 8-4 are similar to the embodiments of FIGS. 5-1 to 5-8, except that contact liners 204 surround the backside contact plugs 164.

After the contact openings 160 (not shown) are formed, contact liners 204 are formed along the sidewalls (e.g., defined by the exposed surfaces of the third interlayer dielectric layer 202, the lower fin elements 103N and 103P, the isolation structure 110) of the contact openings 160 using a deposition process and an etching back process, in accordance with some embodiments. In some embodiments, the contact liners 204 are made of an insulating material such as a dielectric material (e.g., SiC, LaO, AlO, AlON, ZrO, HfO, SiN, ZnO, ZrN, ZrAlO, TiO, TaO, YO, TaCN, ZrSi, SiOCN, SiOC, SiCN, SiN, HfSi, or SiO); or undoped silicon (Si). As a result, the backside contact plugs 164 are surrounded by the contact liners 204, in accordance with some embodiments.

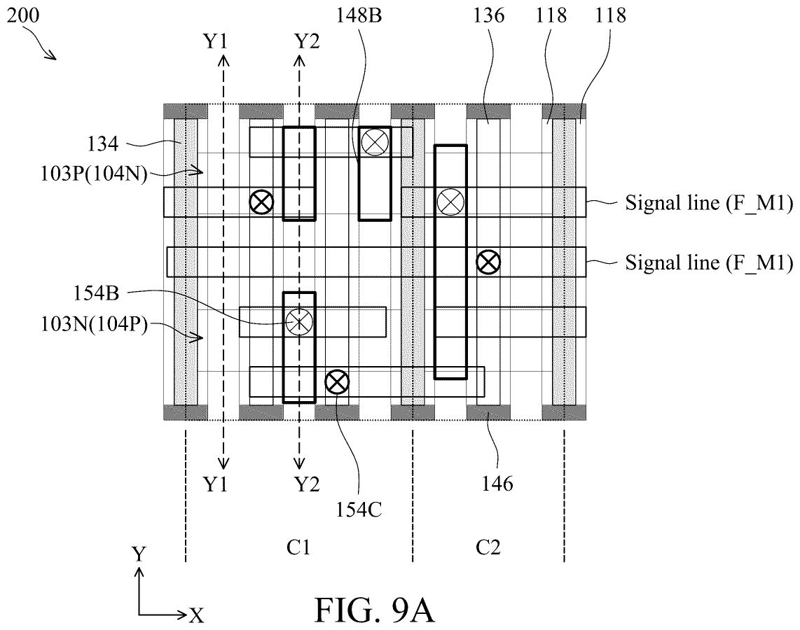

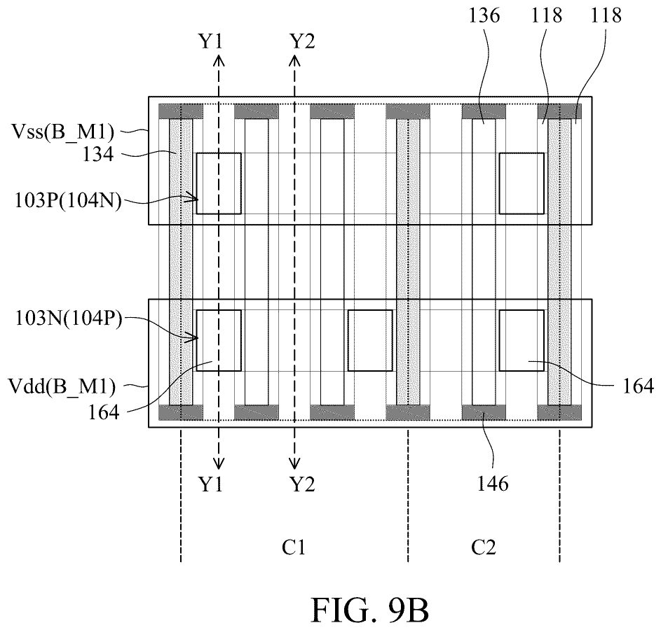

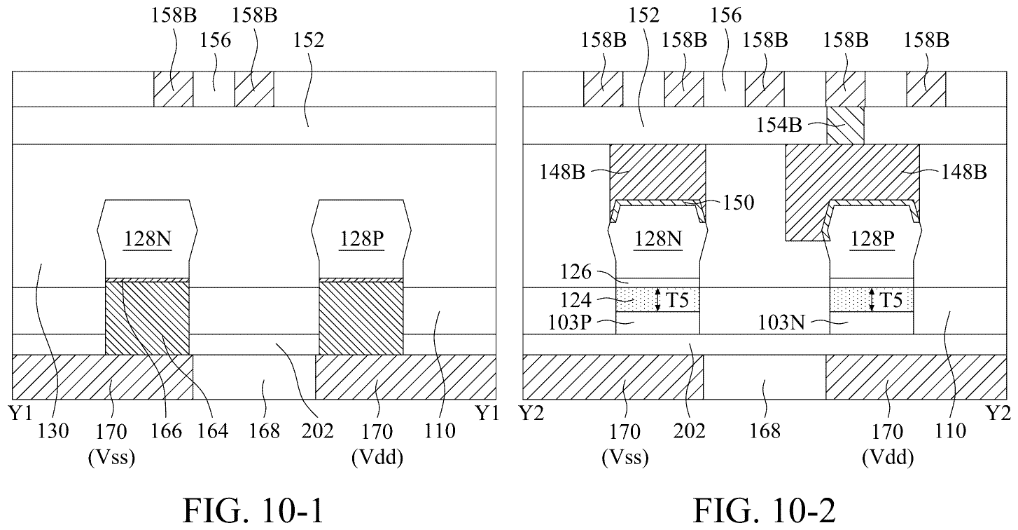

FIGS. 9A and 9B respectively illustrate the frontside layout and the backside layout of a semiconductor structure 200 with a backside power rail architecture, in accordance with some embodiments. FIGS. 10-1 and 10-2 are cross-sectional views of the semiconductor structure 200 respectively corresponding to line Y1-Y1 and line Y2-Y2 of FIGS. 9A and 9B, in accordance with some embodiments of the disclosure. The semiconductor structure 200 is similar to the semiconductor structure 100 of FIGS. 2A and 2B, except that the frontside first metal layer (F_M1) only includes signal lines. The formation of the semiconductor structure 200 may be substantially the same as to the formation of the semiconductor structure 100.

The frontside contact plugs 148A, the vias 154A and the Vdd/Vss frontside power rails are not formed, which may increase the metal line spacing, and/or increase the density of the signal lines in an STD cell, as shown in FIGS. 9A and 10-1, in accordance with some embodiments. The frontside first metal layer (F_M1) only includes the signal lines 158B, which electrically connected to the final gate stacks 136 and the non-Vdd/Vss nodes (e.g., drain terminals) of the n-channel transistors and p-channel transistors through the vias 154B and 154C and the contact plugs 148B, as shown in FIGS. 9A, 9B, 10-1 and 10-2, in accordance with some embodiments. In some embodiments, the maximum number of the signal lines 158B arranged in parallel in an STD cell (e.g., the cell region C1) is five, as shown in FIGS. 9A and 10-2.

As described above, the aspect of the present disclosure is directed to a semiconductor structure with a backside power rail architecture. The semiconductor structure includes the backside metal line 170 below and electrically connected to the Vdd/Vss nodes (e.g., the source/drain features 128N or 128P and the backside contact plugs 164) of the integrated circuits of the cell regions C1 and C2, in accordance with some embodiments. The overall resistance of the BEOL metal layer, and/or the complexity of the metal routing on the frontside of the substrate may be reduced.

In addition, forming the semiconductor structure includes forming the sacrificial layers 124 in the source/drain recesses 120, and forming the source/drain features 128N or 128P on the sacrificial layers 124. As a result, the backside contact plugs 164 can be formed to have narrower portions 164B that replace the sacrificial layer 124 and are thus self-aligned to the source/drain features 128N or 128P. The parasitic capacitance between the backside contact plugs 164 and the final gate stacks 136 may be reduced. Furthermore, the backside contact plugs 164 can be formed to have wider portions 164A connected to the backside metal line 170, thereby improving the RC delay of the metal conductors (e.g., metal lines) and the IR voltage drop of the power supply.

Embodiments of a semiconductor structure and the method for forming the same may be provided. The method for forming a source/drain feature on a sacrificial layer in a source/drain recess, flipping the semiconductor structure, and removing the sacrificial layer to form a lower portion of a contact opening. As a result, the lower portion of the contact opening may be self-aligned to the source/drain feature. Therefore, the continued scaling of the contact-to-poly pitch (CPP) may not be limited by the process window of the photobiography process for forming the backside contact plug, which may facilitate scaling down the semiconductor devices.

In some embodiments, a method for forming a semiconductor structure is provided. The method includes forming an active region over a substrate, etching the active region to form a recess, forming a sacrificial layer in the recess, forming a source/drain feature over the sacrificial layer in the recess, removing the substrate, etching the active region and the sacrificial layer to form an opening exposing a backside surface of the source/drain feature, and forming a first contact plug in the opening.

In some embodiments, a method for forming a semiconductor structure is provided. The method includes forming a plurality of nanostructures over a fin element, forming a first sacrificial layer in the fin element, forming a first source/drain feature over the first sacrificial layer and adjoining the nanostructures, forming a gate stack surrounding the nanostructures, flipping the semiconductor structure upside down, etching the fin element to form a first portion of an opening, and etching the sacrificial layer to form a second portion of the opening. The first portion of the opening is wider than the second portion of the opening. The method also includes forming a first contact plug to fill the opening.

In some embodiments, a semiconductor structure is provided. The semiconductor structure includes a plurality of nanostructures, a gate stack wrapping the nanostructures, a first source/drain feature adjoining the nanostructures, a gate spacer layer between the gate stack and the first source/drain feature, and a first contact plug below and electrically connected to the first source/drain feature. The gate spacer layer overlaps the first contact plug. The semiconductor structure also includes a metal line below and in direct contact with the contact plug.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming an active region over a substrate;
etching the active region to form a recess;
forming a sacrificial layer in the recess;
forming a source/drain feature over the sacrificial layer in the recess;
removing the substrate;
etching the active region and the sacrificial layer to form an opening exposing a backside surface of the source/drain feature; and
forming a first contact plug in the opening.

2. The method for forming the semiconductor structure as claimed in claim 1, further comprising:
forming a second contact plug on a frontside surface of the source/drain feature.

3. The method for forming the semiconductor structure as claimed in claim 2, wherein in a direction parallel to a longitudinal axis of the active region, the second contact plug is narrower than the first contact plug.

4. The method for forming the semiconductor structure as claimed in claim 2, wherein in a direction perpendicular to a longitudinal axis of the active region, the second contact plug is longer than the first contact plug.

5. The method for forming the semiconductor structure as claimed in claim 1, further comprising:
forming a power supply line below and in direct contact with the first contact plug.

6. The method for forming the semiconductor structure as claimed in claim 1, further comprising:
forming an insulating layer between the sacrificial layer and the source/drain feature.

7. The method for forming the semiconductor structure as claimed in claim 1, further comprising:
forming a stack over the substrate, wherein the stack includes first semiconductor layers and second semiconductor layers alternately stacked;
patterning the stack and the substrate into the active region;
forming a dummy gate structure over the active region;
forming a gate spacer layer alongside the dummy gate structure;
removing the dummy gate structure and the first semiconductor layers; and
forming a gate stack surrounding the second semiconductor layers.

8. The method for forming the semiconductor structure as claimed in claim 7, wherein etching the active region and the sacrificial layer to form the opening comprises:
forming a patterned mask layer having an opening pattern corresponding to the source/drain feature, wherein an extension line of a sidewall of the opening pattern passes through the gate spacer layer.

9. A method for forming a semiconductor structure, comprising:
forming a plurality of nanostructures over a fin element;
forming a first sacrificial layer in the fin element;
forming a first source/drain feature over the first sacrificial layer and adjoining the plurality of nanostructures;
forming a gate stack surrounding the plurality of nanostructures;
flipping the semiconductor structure upside down;
etching the fin element to form a first portion of an opening;
etching the first sacrificial layer to form a second portion of the opening, wherein the first portion of the opening is wider than the second portion of the opening; and
forming a first contact plug to fill the opening.

10. The method for forming the semiconductor structure as claimed in claim 9,
wherein the first portion of the opening has a first width, the second portion of the opening has a second width, and a ratio of the first width to the second width is in a range from about 1.15 about 5.

11. The method for forming the semiconductor structure as claimed in claim 9, further comprising:
forming a silicide layer on a surface of the fin element exposed from the opening and on a surface of the first source/drain feature exposed from the opening.

12. The method for forming the semiconductor structure as claimed in claim 9, further comprising:
forming a second sacrificial layer in the fin element;
forming a second source/drain feature on the first sacrificial layer and adjoining the plurality of nanostructures;
forming an interlayer dielectric layer covering the first source/drain feature and the second source/drain feature; and
forming a second contact plug through the interlayer dielectric layer and on the second source/drain feature before flipping the semiconductor structure upside down.

13. The method for forming the semiconductor structure as claimed in claim 12, further comprising:
forming a metal line on and electrically connected to the first contact plug, wherein the metal line is electrically isolated from the second source/drain feature.

14. The method for forming the semiconductor structure as claimed in claim 13, further comprising:
forming a first dummy gate structure and a second dummy gate structure over an active region;
replacing the first dummy gate structure with a gate isolation structure;
patterning the active region into the plurality of nanostructures and the fin element; and
replacing the second dummy gate structure with the gate stack, wherein the gate isolation structure extends into the fin element and is spaced apart from the metal line by the fin element.

15. A semiconductor structure, comprising:
a plurality of nanostructures;
a gate stack wrapping the plurality of nanostructures;
a first source/drain feature adjoining the plurality of nanostructures;
a gate spacer layer between the gate stack and the first source/drain feature;
a first contact plug below and electrically connected to the first source/drain feature, wherein the gate spacer layer overlaps the first contact plug; and
a metal line below and in direct contact with the contact plug.

16. The semiconductor structure as claimed in claim 15, wherein the first contact plug includes an upper portion and a lower portion below the upper portion, a sidewall of the upper portion of the first contact plug is indented from a sidewall of the lower portion of the first contact plug by a distance.

17. The semiconductor structure as claimed in claim 15, further comprising:
a fin element below the first source/drain feature and over the metal line, wherein the first contact plug penetrates through the fin element; and
a second source/drain feature adjoining the plurality of nanostructures, wherein the second source/drain feature is spaced apart from the metal line by the fin element.

18. The semiconductor structure as claimed in claim 17, further comprising:
a dielectric layer below the fin element and over the metal line, wherein the first contact plug further penetrates through the dielectric layer.

19. The semiconductor structure as claimed in claim 15, further comprising:
a second contact plug over and electrically connected to the first source/drain feature, wherein the lower portion of the first contact plug is wider than the second contact plug.

20. The semiconductor structure as claimed in claim 19, wherein the metal line is a Vdd power rail or a Vss power rail.
